(19) United States
(12) Patent Application Publication
(10) Pub. No.: US 2026/0239951 A1
(43) Pub. Date: Aug. 13, 2026

(54) INTEGRATED CIRCUIT STRUCTURES WITH III-N TRANSISTORS AND BACKSIDE VIAS

(71) Applicant: Intel Corporation, Santa Clara, CA (US)

(72) Inventors: Han Wui Then, Portland, OR (US); Marko Radosavljevic, Portland, OR (US); Ahmad Zubair, Beaverton, OR (US); Samuel Bader, Hillsboro, OR (US); Heli Vora, Portland, OR (US); Prafful Golani, Hillsboro, OR (US); Michael Beumer, Portland, OR (US); Pratik Koirala, Portland, OR (US)

(73) Assignee: Intel Corporation, Santa Clara, CA (US)

(21) Appl. No.: 19/050,375

(22) Filed: Feb. 11, 2025

(51) Int. Cl. H01L 23/522; H10D 30/47; H10D 62/85; H10D 84/80

(52) U.S. Cl. CPC H10W 20/42; H10D 30/475; H10D 84/811; H10D 62/8503

(57) ABSTRACT

Disclosed herein are IC structures with III-N transistors and backside vias and associated packages, assemblies, and devices. In one example, an IC structure may include a substrate having a first side and a second side; a semiconductor material over the first side of the substrate, the semiconductor material including gallium and nitrogen; a first conductive backside via; and a second conductive backside via, in which: the first and the second conductive backside vias extend from the second side of the substrate to the first side of the substrate and into the semiconductor material, and a distance between the second side of the substrate and an end of the first conductive backside via in the semiconductor material is different from a distance between the second side of the substrate and an end of the second conductive backside via in the semiconductor material.

### BACKGROUND

Solid-state devices that can be used in high-frequency and/or high voltage applications are of great importance in modern semiconductor technologies. For example, radio frequency (RF) integrated circuits (ICs) (RFICs) and power management integrated circuits (PMICs) may be critical functional blocks in system on a chip (SoC) implementations. Such SoC implementations may be found in mobile computing platforms such as smartphones, tablets, laptops, netbooks, and the like. In such implementations, the RFICs and PMICs are important factors for power efficiency and form factor and can be equally or even more important than logic and memory circuits.

Transistor technologies based on semiconductor materials other than silicon (Si), may be particularly advantageous for high-frequency and high voltage applications. For example, III-N material-based transistors such as gallium nitride (GaN) transistors are being extensively evaluated as an alternative to Si-based transistors due, in part, to the large band gap and high mobility of some III-N materials.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1 is a side, cross-sectional view of an IC structure with a III-N transistor, in accordance with various embodiments.

FIG. 2 is a side, cross-sectional view of an IC structure with III-N transistors and backside thermal vias, in accordance with various embodiments.

FIG. 3 is a side, cross-sectional view of an IC structure with III-N transistors, backside power vias, and capacitors, in accordance with various embodiments.

FIG. 4 is a side, cross-sectional view of an IC structure with III-N transistors, backside power vias, and magnetic cores, in accordance with various embodiments.

FIG. 5 illustrates top views of a wafer and dies that may include one or more IC structures with III-N transistors and backside vias, in accordance with some embodiments.

FIG. 6 is a side, cross-sectional view of an IC device that may include one or more IC structures with III-N transistors and backside vias, in accordance with some embodiments.

FIG. 7 is a side, cross-sectional view of an IC package that may include one or more IC structures with III-N transistors and backside vias, in accordance with some embodiments.

FIG. 8 illustrates a cross-sectional side view of an IC device assembly that may include one or more IC structures with III-N transistors and backside vias, in accordance with some embodiments.

FIG. 9 is a block diagram of an example computing device that may include one or more IC structures with III-N transistors and backside vias, in accordance with some embodiments.

FIG. 10 is a block diagram of an example processing device that may include one or more IC structures with III-N transistors and backside vias, in accordance with some embodiments.

FIG. 11 is a block diagram of an example RF device that may include an IC package including any of the IC structures with III-N transistors and backside vias disclosed herein.

### DETAILED DESCRIPTION

As mentioned above, transistors based on some non-Si semiconductor materials, such as III-N semiconductor materials (e.g., III-N transistors), have properties that make them particularly advantageous for certain applications. For example, because GaN has a larger band gap (about 3.4 electron-volts (eV)) than Si (band gap of about 1.1 eV), a GaN transistor is expected to withstand a larger electric field (resulting, e.g., from applying a large voltage to the drain, Vdd) before suffering breakdown, compared to a Si transistor of similar dimensions. Furthermore, III-N transistors may advantageously employ a 2D electron gas (2DEG) (i.e., a group of electrons, an electron gas, free to move in two dimensions but tightly confined in the third dimension, e.g., a 2D sheet charge) as its transport channel, enabling high mobility without relying on using impurity dopants. For example, the 2DEG may be formed just below a heterojunction interface formed by deposition (e.g., epitaxial deposition) on a given III-N semiconductor material of a charge-inducing film of a material having larger spontaneous and piezoelectric polarization, compared to the III-N semiconductor material. Such a film is generally referred to as a “polarization material” while the III-N semiconductor material adjacent to the polarization material may be referred to as a “III-N channel material” because this is where a conductive channel (2DEG) is formed during operation of the III-N transistor. Together, a stack of a III-N channel material and a polarization material provided thereon may be referred to as a “III-N channel stack” of a III-N transistor. Providing a polarization material such as AlGaN over a III-N channel material such as GaN may induce tensile strain in the polarization material (e.g., due to the lattice mismatch between these two materials; e.g., due to the lattice constant of a polarization material such as AlGaN being smaller than that of the III-N semiconductor material such as GaN), which allows forming very high charge densities in the underlying III-N channel material without intentionally adding impurity dopants. As a result, high mobility of charge carriers in the III-N channel material may, advantageously, be realized.

Disclosed herein are IC structures with III-N transistors and backside vias and associated packages, assemblies, and devices. Improving the power density of power electronics solutions without compromising power efficiency remains a significant challenge in the industry. To address this, III-N devices (e.g., III-N transistors such as GaN transistors) are being adopted for their unique ability to handle higher voltages, high current densities, and exceptional efficiency, making them ideal for delivering power to central processing units (CPUs) and graphics processing units (GPUs). Looking to the future, as the demand for ever-smaller solutions outpaces previous generations, technologies enabling three-dimensional (3D) stacking of ICs are becoming indispensable. A critical enabler of this advancement is through-substrate vias (TSVs). Embodiments of the present disclosure are based on leveraging TSVs (which may also be referred to as “backside vias” because they extend from the back side of the substrate to the front side of the substrate and into further layers formed on the front side) to integrate added functionalities such as power, signal, and thermal management into designs. IC structures with III-N transistors and backside vias, disclosed herein, may help reduce power dissipation, thereby enhancing efficiency and performance.

In one example, an IC structure may include a substrate having a first side and a second side; a semiconductor material over the first side of the substrate, the semiconductor material including gallium and nitrogen; a first conductive via; and a second conductive via, in which: the first conductive via and the second conductive via extend from the second side of the substrate to the first side of the substrate and into the semiconductor material, and a distance between the second side of the substrate and an end of the first conductive via in the semiconductor material is different from a distance between the second side of the substrate and an end of the second conductive via in the semiconductor material. In another example, an IC structure may include a substrate having a first side and a second side; a semiconductor material over the first side of the substrate, the semiconductor material including gallium and nitrogen; an insulator material over the semiconductor material; a transistor over the first side of the substrate, in which a portion of the semiconductor material is a channel region of the transistor; a first conductive via; a second conductive via; and a capacitor extending from the second side of the substrate into the substrate, in which: the first conductive via and the second conductive via extend from the second side of the substrate to the first side of the substrate, through the semiconductor material, and into the layer of the insulator material, the first conductive via is electrically connected to a first capacitor electrode of the capacitor, and the second conductive via is electrically connected to a second capacitor electrode of the capacitor. In yet another example, an IC structure may include a substrate having a first side and a second side; a semiconductor material over the first side of the substrate, the semiconductor material including gallium and nitrogen; an insulator material over the semiconductor material; a transistor over the first side of the substrate, in which a portion of the semiconductor material is a channel region of the transistor; a first conductive via; a second conductive via; and a magnetic inductor including a structure of a magnetic material (e.g., a magnetic core of the magnetic inductor) extending from the second side of the substrate into the substrate, in which: the first conductive via and the second conductive via extend from the second side of the substrate to the first side of the substrate, through the semiconductor material, and into the layer of the insulator material, the first conductive via is electrically connected to the second conductive via, and the structure of the magnetic material is between the first conductive via and the second conductive via. In all of these examples, the first and second conductive vias are backside vias.

As used herein, the term “III-N semiconductor material” (or, simply, “III-N material”) refers to a compound semiconductor material with a first sub-lattice of at least one element from group III of the periodic table (e.g., Al, Ga, In) and a second sub-lattice of nitrogen (N). As used herein, the term “III-N transistor” refers to a field-effect transistor (FET) that includes a III-N material (which may include one or more different III-N materials, e.g., a plurality of different III-N materials stacked over one another) as an active material (i.e., the material in which a conducting channel of the transistor forms during operation, in which context the III-N material may also be referred to as a “III-N channel material”).

While various embodiments described herein refer to III-N transistors (i.e., transistors employing one or more III-N materials as an active channel material), these embodiments are equally applicable to any other III-N devices besides III-N transistors, such as III-N diodes, sensors, light-emitting diodes (LEDs), and lasers (i.e., other device components employing one or more III-N materials as active materials). Furthermore, while discussions provided herein refer to the two-dimensional charge carrier layers as “2DEG” layers, embodiments described herein are also applicable to systems and material combinations in which 2D hole gas (2DHG) may be formed, instead of 2DEG. Thus, unless stated otherwise, explanations of embodiments referring to 2DEG may be applied to transistors implementing 2DHG instead, all of such embodiments being within the scope of the present disclosure.

In the following detailed description, various aspects of the illustrative implementations may be described using terms commonly employed by those skilled in the art to convey the substance of their work to others skilled in the art. For example, the term “connected” means a direct electrical connection between the things that are connected (e.g., with the things being in electrically conductive and/or physical contact with), without any intermediary devices, while the term “coupled” means either a direct electrical connection between the things that are connected, or an indirect connection through one or more passive or active intermediary devices. Describing A and B are being “in contact” includes A and B being in direct physical contact, possibly with an interface that may form when A and B are brough into direct physical contact with one another. The term “circuit” means one or more passive and/or active components that are arranged to cooperate with one another to provide a desired function. The terms “oxide,” “carbide,” “nitride,” etc. refer to compounds containing, respectively, oxygen, carbon, nitrogen, etc. Similarly, the terms naming various compounds refer to materials having any combination of the individual elements within a compound (e.g., “gallium nitride” or “GaN” refers to a material that includes gallium and nitrogen, “aluminum gallium nitride” or “AlGaN” refers to a material that includes aluminum, gallium and nitrogen, and so on). Further, the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2% of a target value based on the context of a particular value as described herein or as known in the art. Since, as is commonly known, designations of “source” and “drain” may be interchangeable in transistors, the notation “S/D” (source/drain) may be used herein to refer to either the source or the drain of the transistor, indicating their interchangeability.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

Although certain elements may be referred to in the singular herein, such elements may include multiple sub-elements. For example, “an insulator material” may include one or more insulator materials. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. For example, the term “insulator material” may refer to solid materials (and/or liquid materials that solidify after processing as described herein) that are substantially electrically non-conducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. With reference to optical signals and/or devices, components and elements that operate on or using optical signals, the term “conducting/conductive” can also mean “optically conducting/conductive.”

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

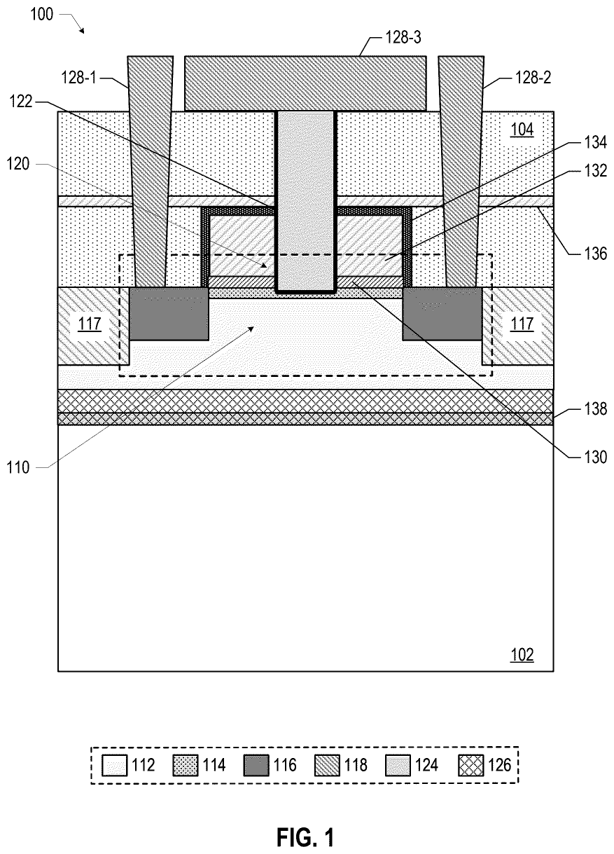

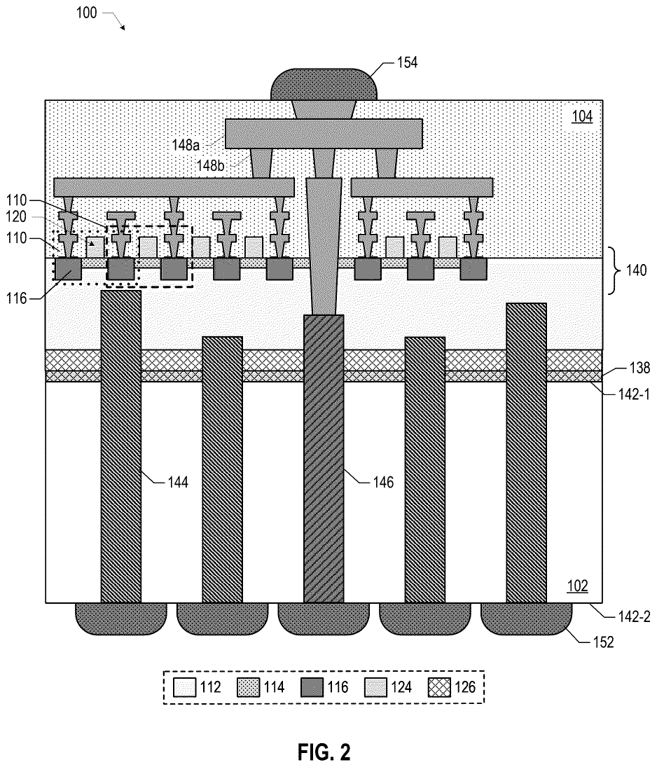

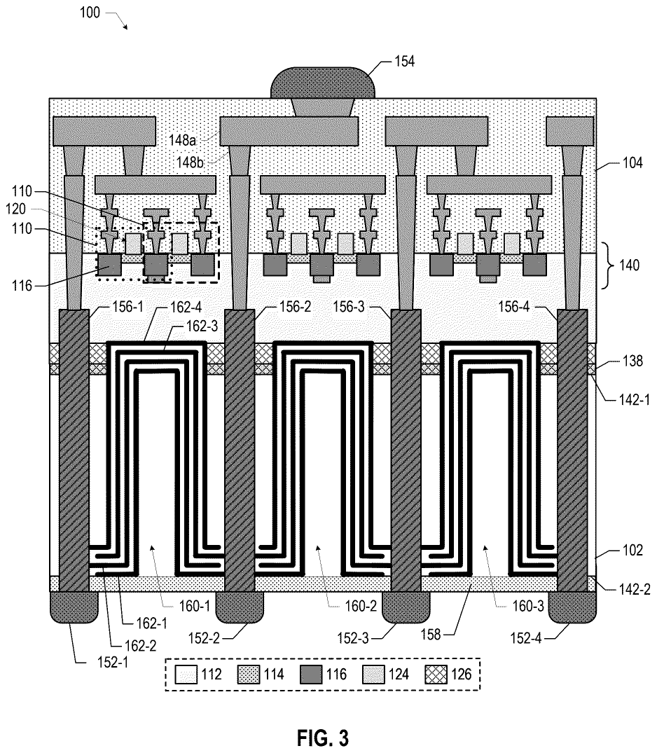

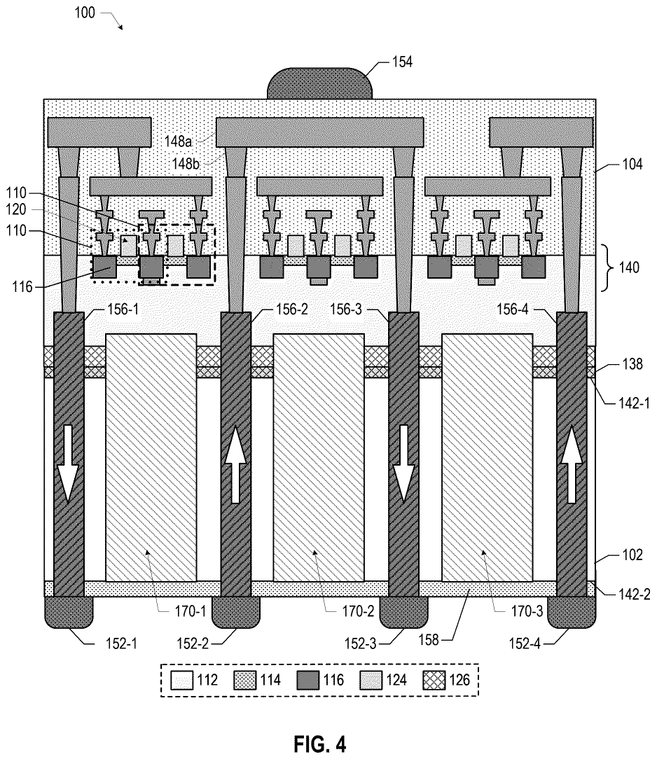

A number of examples of IC structures with III-N transistors and backside vias are disclosed herein. Although these IC structures may be separately discussed for ease of illustration, any suitable ones of these arrangements may be combined in an IC structure, an IC package, or an IC assembly. For example, one portion of an IC structure may include an arrangement as shown in FIG. 2, while another portion of the same IC structure may include an arrangement as shown in FIG. 3 or FIG. 4. This particular set of combinations is just an example, and any suitable combination of any of the embodiments disclosed herein are within the scope of this disclosure. More generally, any of the arrangements discussed with reference to FIGS. 1-4 may be included in an IC structure in combination with any of the other arrangements as discussed with reference to FIGS. 1-4.

The drawings are not necessarily to scale. In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures with III-N transistors and backside vias as described herein.

Various IC structures with III-N transistors and backside vias as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in various applications, such as microprocessors, optoelectronics, logic blocks, audio amplifiers, etc., depending on the components associated with the IC. In some embodiments, IC structures as described herein may be included in a RFIC, which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. The IC may be employed as part of a chipset for executing one or more related functions on a computer.

FIG. 1 is a side, cross-sectional view of an IC structure 100 with a III-N transistor 110 (an approximate boundary of which is illustrated in FIG. 1 with a dashed line), in accordance with various embodiments. A legend provided within a dashed box at the bottom of each of FIGS. 1-4 illustrates colors/patterns used to indicate some classes of materials of some of the elements shown in FIGS. 1-4, so that FIGS. 1-4 are not cluttered by too many reference numerals. For example, FIG. 1 uses different colors/patterns to identify a III-N material 112, a polarization material 114, S/D regions 116 of the III-N transistor 110, an electrically conductive material 118 (e.g., used to implement contacts to various transistor terminals), a gate electrode material 124 of the III-N transistor 110, and a buffer material 126.

As shown in FIG. 1, the III-N transistor may be provided over a substrate 102. The substrate 102 may be any suitable structure, e.g., a substrate, a die, or a chip, on/in which III-N transistors and backside vias as described herein may be implemented. In some embodiments, the substrate 102 may include a semiconductor, such as silicon. In other implementations, the substrate 102 may include/be alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N or group IV materials. In some embodiments, the substrate 102 may include a ceramic material, or any other non-semiconductor material. For example, in some embodiments, the substrate 102 may include glass, a combination of organic and inorganic materials, embedded portions having different materials, etc. Although a few examples of materials from which the substrate 102 may be formed are described here, any material that may serve as a foundation upon which III-N transistors and backside vias as described herein may be built falls within the spirit and scope of the present disclosure.

As is further shown in FIG. 1, an insulator 104 may be provided over the substrate 102 to isolate some portions of the IC structure 100 from the others, as needed. The insulator 104 may include any suitable insulating material, such as any suitable interlayer dielectric (ILD), silicon oxide, silicon nitride, aluminum oxide, and/or silicon oxynitride. In some embodiments, the insulator 104 may be a low-k dielectric. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass. In general, the insulator 104 may be provided in various portions of the IC structure 100. In some embodiments, the insulator 104 may include a continuous insulator material encompassing at least portions of the III-N transistor 110. In various embodiments, the insulator 104 may include different insulating materials in different portions of the IC structure 100. In some embodiments, the substrate 102 of the IC structure 100 may include an insulator layer, such as an oxide isolation layer, provided thereon. For example, in some embodiments, although not specifically shown in FIG. 1, a layer of the insulator 104 may be provided over the substrate 102 but below the III-N material 112. The insulator on the substrate 102 may include any suitable insulating material to electrically isolate the semiconductor material of the substrate 102 from other regions of or surrounding the III-N transistor 110. Providing such an insulating layer over the substrate 102 may help mitigate the likelihood that conductive pathways will form through the substrate 102 (e.g., a conductive pathway between the S/D regions 116).

As shown in FIG. 1, a III-N material 112 may be provided over the substrate 102, where a channel region of the III-N transistor 110 may include a portion of the III-N material 112. In some embodiments, the III-N material 112 may be formed of a compound semiconductor with a first sub-lattice of at least one element from group III of the periodic table (e.g., Al, Ga, In), and a second sub-lattice of nitrogen (N). In some embodiments, the III-N material 112 may be a binary, ternary, or quaternary III-N compound semiconductor that is an alloy of two, three, or even four elements from group III of the periodic table (e.g., boron, aluminum, indium, gallium) and nitrogen.

In general, the III-N material 112 may be composed of various III-N semiconductor material systems including, for example, N-type or P-type III-N materials systems, depending on whether the III-N transistor 110 is an N-type or a P-type transistor. For some N-type transistor embodiments, the III-N material 112 may advantageously be an III-N material having a high electron mobility, such a, but not limited to GaN, InGaAs, InP, InSb, and InAs. For some InₓGa₁₋ₓ As embodiments, In content (x) may be between 0.6 and 0.9, and advantageously is at least 0.7 (e.g., In_{0.7}Ga_{0.3}As). For some such embodiments, the III-N material 112 may be a ternary III-N alloy, such as InGaN, or a quaternary III-N alloy, such as AlInGaN.

In some embodiments, the III-N material 112 may be a semiconductor material having a band gap greater than a band gap of silicon (i.e., greater than about 1.1 eV), e.g., greater than 1.5 eV, or greater than 2 eV. Thus, in such embodiments, the III-N material 112 may include, e.g., GaN, AlN, or any alloy of Al, Ga, and N, but not InN because InN has a band gap of only about 0.65 eV.

In some embodiments, the III-N material 112 may be formed of a highly crystalline semiconductor, e.g., of substantially a monocrystalline semiconductor (possibly with some limited amount of defects, e.g., dislocations). The quality of the III-N material 112 (e.g., in terms of defects or crystallinity) may be higher than that of other III-N materials of, or near, the III-N transistor 110 since, during the operation of the III-N transistor 110, a transistor channel will form in the III-N material 112. A portion of the III-N material 112 where a transistor channel of the III-N transistor 110 forms during operation may be referred to as a “III-N channel material/region” of the III-N transistor 110.

In some embodiments, the III-N material 112 may be an intrinsic III-N semiconductor material or alloy, not intentionally doped with any electrically active impurity. In alternate embodiments, one or more a nominal impurity dopant level may be present within the III-N material 112, for example to set a threshold voltage Vt of the III-N transistor 110, or to provide halo pocket implants, etc. In such impurity-doped embodiments however, impurity dopant level within the III-N material 112 may be relatively low, for example below 10¹⁵ dopants per cubic centimeter (cm⁻³), or below 10¹³cm⁻³.

In various embodiments, a thickness of the III-N material 112 may be between about 5 and 2000 nanometers, including all values and ranges therein, e.g., between about 50 and 1000 nanometers, or between about 10 and 50 nanometers. Unless specified otherwise, all thicknesses described herein refer to a dimension measured in a direction perpendicular to the substrate 102.

Turning now to the polarization material 114 of the III-N transistor 110, in general, the polarization material 114 may be a layer of a charge-inducing film of a material having larger spontaneous and/or piezoelectric polarization than that of the bulk of the III-N layer material immediately below it (e.g., the III-N material 112), creating a heterojunction (i.e., an interface that occurs between two layers or regions of semiconductors having unequal band gaps) with the III-N material 112, and leading to formation of 2DEG at or near (e.g., immediately below) that interface, during operation of the III-N transistor 110. As described above, a 2DEG layer may be formed during operation of an III-N transistor in a layer of an III-N semiconductor material immediately below a suitable polarization layer. In various embodiments, the polarization material 114 may include materials such as AlN, InAlN, AlGaN, or AlₓIn_{y}Ga_{1-x-y}N, and may have a thickness between about 1 and 50 nanometers, including all values and ranges therein, e.g., between about 5 and 15 nanometers or between about 10 and 30 nanometers. Although both the III-N material 112 and the polarization material 114 are III-N semiconductor materials, their material compositions are different. In some embodiments, both the III-N material 112 and the polarization material 114 may be substantially crystalline materials, but with different lattice constants.

As also shown in FIG. 1, the III-N transistor 110 may include two S/D regions 116, where one of the S/D regions 116 is a source region and the other one of the S/D regions 116 is a drain region. As is well-known, in a transistor, S/D regions (also sometimes interchangeably referred to as “diffusion regions”) are regions that can supply charge carriers for the transistor channel (e.g., the transistor channel of the III-N material 112) of the transistor (e.g., the III-N transistor 110). In some embodiments, the S/D regions 116 may include doped semiconductor materials, such as doped InGaN. Often, the S/D regions may be highly doped, e.g., with dopant concentrations of at least above 1·10¹⁹ dopants per cubic centimeter (cm⁻³), e.g., at least above 1·10²⁰ cm⁻³ or at least above 1·10²¹ cm⁻³, in order to advantageously form Ohmic contacts with the respective S/D contacts, although the S/D regions 116 may also have lower dopant concentrations in some implementations. Regardless of the exact doping levels, the S/D regions 116 are the regions having dopant concentration higher than in other regions between the source region (e.g., the S/D region 116 shown on the left side in FIG. 1) and the drain region (e.g., the S/D region 116 shown on the right side in FIG. 1), i.e., higher than the III-N material 112. In further embodiments, one or more layers of metal and/or metal alloys may be used to form the S/D regions 116.

In some embodiments, isolation structures 117 may be provided on either side of the S/D regions 116, e.g., to electrically separate the S/D regions 116 of the III-N transistor 110 from S/D regions of other transistors. The isolation structures 117 may include any suitable insulator material, e.g., any of the low-k dielectric materials described herein. The isolation structures 117 may be referred to as “shallow trench insulator” (STI).

As shown in FIG. 1, contacts 128 (which may also be referred to as “electrodes” or “terminals”) of the III-N transistor 110 may include a contact 128-1 to one of the S/D regions 116, a contact 128-2 to the other one of the S/D regions 116, and a contact 128-3 to the gate stack of the III-N transistor 110. The contacts 128 may be made of, or may include, an electrically conductive material 118. The electrically conductive material 118 of the contacts 128 may include any suitable electrically conductive material, alloy, or a stack of multiple electrically conductive materials. In some embodiments, the electrically conductive material 118 may include one or more metals or metal alloys, with metals such as copper, ruthenium, palladium, platinum, cobalt, nickel, hafnium, zirconium, titanium, tantalum, and aluminum, tantalum nitride, titanium nitride, tungsten, doped silicon, doped germanium, or alloys and mixtures of these. In some embodiments, the electrically conductive material 118 may include one or more electrically conductive alloys, oxides, or carbides of one or more metals. In some embodiments, the electrically conductive material 118 may include a doped semiconductor, such as silicon or another semiconductor doped with an N-type dopant or a P-type dopant. Metals may provide higher conductivity, while doped semiconductors may be easier to pattern during fabrication. In some embodiments, the contacts 128 may have a thickness between about 2 nanometers and 1000 nanometers, e.g., between about 2 nanometers and 100 nanometers. In general, the electrically conductive material 118 may also be used to form electrical contacts to any of the transistor terminals of the III-N transistor 110.

FIG. 1 further illustrates a gate stack 120 provided over the channel portion of the III-N material 112. As shown in FIG. 1, in some embodiments, the gate stack 120 may include a layer of a gate insulator 122 and a gate electrode material 124. In other embodiments, the gate insulator 122 may be omitted from the gate stack 120.

In some embodiments, the gate insulator 122 may be a high-k dielectric material, e.g., a material including elements such as hafnium, silicon, oxygen, titanium, tantalum, lanthanum, aluminum, zirconium, barium, strontium, yttrium, lead, scandium, niobium, and zinc. Examples of high-k materials that may be used in the gate insulator 122 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator 122 during manufacture of the III-N transistor 110 to improve the quality of the gate insulator 122. A thickness of the gate insulator 122 may be between 0.5 nanometers and 3 nanometers, including all values and ranges therein, e.g., between 1 and 3 nanometers, or between 1 and 2 nanometers.

The gate electrode material 124 may include at least one P-type work function metal or N-type work function metal, depending on whether the III-N transistor 110 is a P-type metal-oxide-semiconductor (PMOS) transistor or an N-type metal-oxide-semiconductor (NMOS) transistor (e.g., P-type work function metal may be used as the gate electrode material 124 when the III-N transistor 110 is a PMOS transistor and N-type work function metal may be used as the gate electrode material 124 when the III-N transistor 110 is an NMOS transistor, depending on the desired threshold voltage). For a PMOS transistor, metals that may be used for the gate electrode material 124 may include, but are not limited to, ruthenium, palladium, platinum, cobalt, nickel, titanium nitride, and conductive metal oxides (e.g., ruthenium oxide). For an NMOS transistor, metals that may be used for the gate electrode material 124 include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and nitrides of these metals (e.g., tantalum nitride, and tantalum aluminum nitride). In some embodiments, the gate electrode material 124 may include a stack of two or more metal layers, where one or more metal layers are work function metal layers and at least one metal layer is a fill metal layer.

Further layers may be included next to the gate electrode material 124 for other purposes, such as to act as a diffusion barrier layer or/and an adhesion layer, not specifically shown in FIG. 1. Furthermore, in some embodiments, the gate insulator 122 and the gate electrode material 124 may be surrounded by a gate spacer, not shown in FIG. 1, configured to provide separation between the gates of different transistors. Such a gate spacer may be made of a low-k dielectric material (i.e., a dielectric material that has a lower dielectric constant (k) than silicon dioxide which has a dielectric constant of 3.9). Examples of low-k materials that may be used as the dielectric gate spacer may include, but are not limited to, fluorine-doped silicon dioxide, carbon-doped silicon dioxide, spin-on organic polymeric dielectrics such as polyimide, polynorbornenes, benzocyclobutene, and polytetrafluoroethylene (PTFE), or spin-on silicon-based polymeric dielectric such as hydrogen silsesquioxane (HSQ) and methylsilsesquioxane (MSQ)). Other examples of low-k materials that may be used as the dielectric gate spacer include various porous dielectric materials, such as for example porous silicon dioxide or porous carbon-doped silicon dioxide, where large voids or pores are created in a dielectric in order to reduce the overall dielectric constant of the layer, since voids can have a dielectric constant of nearly 1.

In some embodiments, the IC structure 100 may, optionally, include a buffer material 126 between the III-N material 112 and the substrate 102. In some embodiments, the buffer material 126 may be a layer of a semiconductor material that has a band gap larger than that of the III-N material 112, so that the buffer material 126 can serve to prevent current leakage from the future III-N transistor to the substrate 102. A properly selected semiconductor for the buffer material 126 may also enable better epitaxy of the III-N material 112 thereon, e.g., it may improve epitaxial growth of the III-N material 112, for instance in terms of a bridge lattice constant or amount of defects. For example, a semiconductor that includes aluminum, gallium, and nitrogen (e.g., AlGaN) or a semiconductor that includes aluminum and nitrogen (e.g., AlN) may be used as the buffer material 126 when the III-N material 112 is a semiconductor that includes gallium and nitrogen (e.g., GaN). Other examples of materials for the buffer material 126 may include materials typically used as ILD, described above, such as oxide isolation layers, e.g., silicon oxide, silicon nitride, aluminum oxide, and/or silicon oxynitride. When implemented in the III-N transistor 110, the buffer material 126 may have a thickness between about 100 and 5000 nm, including all values and ranges therein, e.g., between about 200 and 1000 nanometers, or between about 250 and 500 nanometers.

In some embodiments, the IC structure 100 may, optionally, include an oxide material 130 (e.g., a layer of a dielectric material that includes oxygen, e.g., a material that includes a metal and oxygen, e.g., aluminum oxide) over the channel region of the III-N transistor 110, e.g., directly on the polarization material 114. In some embodiments, the IC structure 100 may, optionally, include a nitride material 132 (e.g., a layer of a dielectric material that includes nitrogen, e.g., a material that includes a semiconductor and nitrogen, e.g., silicon nitride) over the channel region of the III-N transistor 110, e.g., directly on the oxide material 130 so that the oxide material 130 is between the polarization material 114 and the nitride material 132. In such embodiments, the gate stack 120 may extend through the nitride material 132 and the oxide material 130 and at least partially into the polarization material 114. In some embodiments, a thickness of the oxide material 130 may be between about 2 nanometers and 10 nanometers, including all ranges and values therein, e.g., between about 3 nanometers and 8 nanometers, or around 5 nanometers. In some embodiments, a thickness of the nitride material 132 may be between about 20 nanometers and 100 nanometers, including all ranges and values therein, e.g., between about 25 nanometers and 50 nanometers, or between about 30 nanometers and 50 nanometers. In some embodiments, the IC structure 100 may, optionally, include a layer of a further oxide material 134 (e.g., a layer of a dielectric material that includes oxygen, e.g., a material that includes a semiconductor and oxygen, e.g., silicon oxide) over and on the sidewalls of the nitride material 132. In some embodiments, the IC structure 100 may, optionally, include a layer of a further nitride material 136 (e.g., a layer of a dielectric material that includes nitrogen, e.g., a material that includes a semiconductor and nitrogen, e.g., silicon nitride) over nitride material 132 and over the further oxide material 134. In some embodiments, a thickness of the further oxide material 134 may be between about 10 nanometers and 50 nanometers, including all ranges and values therein, e.g., between about 15 nanometers and 40 nanometers, or between about 20 nanometers and 30 nanometers. In some embodiments, a thickness of the further nitride material 136 may be between about 2 nanometers and 15 nanometers, including all ranges and values therein, e.g., between about 2 nanometers and 10 nanometers, or between about 3 nanometers and 5 nanometers. In such embodiments, a portion of the further oxide material 134 may be between the nitride material 132 and the further nitride material 136, and the further nitride material 136 may be between a portion of the further oxide material 134 and the insulator 104.

Together, the oxide material 130, the nitride material 132, the further oxide material 134, and the further nitride material 136 form a vertical oxide-nitride-oxide-nitride (ONON) stack above the polarization material 114. In such embodiments, the gate stack 120 may extend through the further nitride material 136, the further oxide material 134, the nitride material 132, and the oxide material 130 and at least partially into the polarization material 114. Oxide layers of the ONON stack may offer good electrical isolation and interface quality, while nitride layers of the ONON stack may offer excellent thermal stability and relatively high dielectric constant. As a result, the ONON stack may help improve device performance and reliability by reducing or preventing contamination and damage to the delicate structures of the III-N materials below (e.g., to the III-N material 112) during fabrication process. In context of the ONON stack, the term “oxide material” refers to a dielectric material that does not include nitrogen in the amounts beyond accidental impurities, e.g., an oxide material having nitrogen impurity levels below about 10 part per million (ppm), e.g., below about 1 ppm. Similarly, in context of the ONON stack, the term “nitride material” refers to a dielectric material that does not include oxygen in the amounts beyond accidental impurities, e.g., a nitride material having oxygen impurity levels below about 10 ppm, e.g., below about 1 ppm.

As further shown in FIG. 1, in some embodiments, a further III-N material 138 may be provided between the substrate 102 and the III-N material 112, e.g., between the substrate 102 and the buffer material 126, as shown in FIG. 2. The further III-N material 138 may be a semiconductor material but may have a different material composition than that of the III-N material 112 or of the buffer material 126. For example, in some embodiments, the further III-N material 138 may be a semiconductor material comprising aluminum and nitrogen (e.g., aluminum nitride). In various embodiments, any of the oxide material 130, the nitride material 132, the further oxide material 134, the further nitride material 136, and the further III-N material 138 may be absent from the IC structure 100.

Although not specifically shown in FIG. 1, the IC structure 100 may further include additional transistors similar to the III-N transistor 110, described above.

FIG. 2 is a side, cross-sectional view of an IC structure 100 with III-N transistors 110 and backside thermal vias, in accordance with various embodiments. The IC structure 100 of FIG. 2 may be an example of the IC structure 100 of FIG. 1, but where multiple III-N transistors 110 may be provided with their channel regions being in different portions of the III-N material 112 (two such III-N transistors 110 are labeled in FIG. 2, approximate boundaries of which are illustrated in FIG. 2 with a dotted line and a dashed line). For each of the III-N transistors 110 shown in FIG. 2, details of the transistors are not shown and only their S/D regions 116 and their gate electrode materials 124 are shown. FIG. 2 further provides an example illustration of how electrically conductive features of a device layer 140 (e.g., the gate stack 120 and the S/D regions 116 of the III-N transistors 110) of the IC structure 100 may be electrically coupled with interconnect structures 148 of various interconnect layers provided in the insulator 104. In some embodiments, the interconnect structures 148 may include conductive lines 148a and/or conductive vias 148b filled with an electrically conductive material, e.g., any of the materials described with reference to the electrically conductive material 118. The interconnect structures 148 of the IC structure 100 may be arranged within the insulator 104 to route electrical signals according to a wide variety of designs (in particular, the arrangement is not limited to the particular configuration of interconnect structures 148 depicted in FIG. 2). Descriptions provided with respect to the interconnect structures 2128 of FIG. 6 are applicable to the interconnect structures 148 of FIG. 2.

Turning to the descriptions of the backside vias of the IC structure 100, FIG. 2 illustrates that the substrate 102 may have a front side 142-1 (e.g., the top side of the illustration of FIG. 2) and a back side 142-2 (e.g., the bottom side of the illustration of FIG. 2). Conductive backside vias may be provided from the back side 142-2, extending through the substrate 102 to the front side front side 142-1, and at least partially into the III-N material 112. FIG. 2 illustrates such backside vias as backside thermal vias 144 and, optionally, a backside power via 146. A material similar to the electrically conductive material 118 may be used to at least partially fill backside vias of the IC structure 100 of FIG. 2. In various embodiments, the exact material compositions of the electrically conductive material 118 may be different when used to implement contacts of different terminals of the III-N transistor 110 and when used to implement backside vias of the IC structures 100.

Various ones of the backside vias of the IC structure 100 may be coupled to (e.g., be directly electrically connected to) conductive contacts 152 at the back side 142-2 of the substrate 102, as shown in FIGS. 2-4. Various ones of the interconnect structures 148 may be coupled to (e.g., be directly electrically connected to) conductive contacts 154 at the top of the insulator 104. In FIGS. 2-4, the conductive contacts 152 and conductive contacts 154 are illustrated as taking the form of bond pads, but, in other embodiments, the conductive contacts 152 and conductive contacts 154 may include other analogous features (e.g., posts). The conductive contacts 154 may be electrically coupled with the interconnect structures 148 and configured to route the electrical signals of the III-N transistor(s) 110 to external devices. Descriptions provided with respect to the conductive contacts 2136 of FIG. 6 are applicable to the conductive contacts 152 and conductive contacts 154 of FIGS. 2-4. For the IC structure 100 of FIG. 2, some of the conductive contacts 152 may be electrically coupled, e.g., by means of the backside power via 146 and the interconnect structures 148, to terminals of the III-N transistor(s) 110, e.g., to provide power and/or signals from external devices to the III-N transistor(s) 110. Other ones of the conductive contacts 152 may be thermally coupled with respective backside thermal vias 144, as also shown in FIG. 2.

The backside thermal vias 144 may include vias, pads, and/or lines in the substrate 102, and may serve as thermal pathways to dissipate heat. In some embodiments, the backside thermal vias 144 may not be coupled to any signal or power pathways in the IC structure 100 (e.g., the backside thermal vias 144 may be electrically isolated from all signal and power pathways in the IC structure 100). In some embodiments, one or more of the backside thermal vias 144 may be electrically connected to a ground pathway in the IC structure 100. During operation of the IC structure 100, the backside thermal vias 144 may help transfer the heat from various active components of the IC structure 100 (e.g., from the III-N transistors 110) to the back side 142-2 of the substrate 102, where it may dissipate. In some embodiments, the buffer material 126 may have a lower thermal conductivity than that of the III-N material 112 and lower than that of the substrate 102. In such embodiments, in order to be the most effective, the backside thermal vias 144 extend all the way through the thickness of the buffer material 126 and into the III-N material 112. As shown in FIG. 2, in some embodiments, the backside thermal vias 144 may be of different heights, e.g., a distance between the back side 142-2 of the substrate 102 and an opposite end of one of the backside thermal vias 144 (i.e., the end that is in the III-N material 112) may be different from a distance between the back side 142-2 and an opposite end of another one of the backside thermal vias 144. Implementing backside thermal vias 144 with different heights may advantageously allow tailoring solutions to different design needs. For example, because the associated fringe parasitic effects (e.g., stray coupling capacitance) are generally higher with backside thermal vias of taller heights (e.g., closer to transistor active region), such vias may be less desirable for high-speed and/or high-frequency applications. In such scenarios, a design that uses thermal vias with decreased heights may be advantageous in terms of reduced fringe parasitic effects.

The backside power via 146 may be electrically coupled to one of the conductive contacts 152 at the back side 142-2 and electrically coupled to one or more of the interconnect structures 148, and, therefore, to one or more terminals of the III-N transistor(s) 110, e.g., to provide power and/or signals from external devices to the III-N transistor(s) 110. In some embodiments, the backside power via 146 may extend into the insulator 104 and be connected to a signal pathway or a power pathway in the IC structure 100, e.g., by means of one or more of the interconnect structures 148.

FIG. 3 is a side, cross-sectional view of an IC structure 100 with III-N transistors 110, backside power vias, and capacitors, in accordance with various embodiments. The IC structure 100 of FIG. 3 is similar to the IC structure 100 of FIG. 2 and, therefore, only the differences are described. As shown in FIG. 3, the IC structure 100 may include a plurality of backside power vias 156 (individually labeled as backside power vias 156-1, 156-2, 156-3, and 156-4) and one or more capacitors 160 (individually labeled as capacitors 160-1, 160-2, and 160-3). Both the plurality of backside power vias 156 and the capacitors 160 may extend from the back side 142-2 of the substrate 102 into the substrate 102, where an individual capacitor 160 may be provided between two adjacent backside power vias 156. In some embodiments, the IC structure 100 of FIG. 3 may be a different portion of the IC structure 100 of FIG. 2, i.e., in some embodiments, an IC structure 100 may include both the backside thermal vias 144 of different heights and the backside capacitors 160 and the plurality of backside power vias 156. In other embodiments, the IC structure 100 of FIG. 3 may be an alternative to the IC structure 100 of FIG. 2.

Any of the capacitors 160 may be implemented as a metal-insulator-metal (MIM) capacitor having at least a capacitor plate 162-1 and a capacitor plate 162-2, separated by a capacitor insulator. In some embodiments, any of the capacitors 160 may include two or more capacitor plates implementing one electrode of the capacitor, and two or more capacitor plates implementing another electrode of the capacitor. For example, as shown in FIG. 3, any of the capacitors 160 may further include a capacitor plate 162-3 and a capacitor plate 162-4, also separated by a capacitor insulator. As shown in FIG. 3, for all of the capacitors 160, the capacitor plates 162 may be stacked so that the capacitor plate 162-2 is between the capacitor plates 162-1 and 162-3, and separated therefrom by a capacitor insulator, and so that the capacitor plate 162-3 is between the capacitor plates 162-2 and 162-4 and separated therefrom by a capacitor insulator. Any of the capacitor plates 162 may include any suitable electrically conductive material, e.g., any of the materials described with reference to the electrically conductive material 118. A capacitor insulator separating adjacent ones of the capacitor plates 162 of the capacitor 160 may include any suitable insulator material, e.g., any of the insulator materials described with reference to the insulator 104 or gate insulator 122. FIG. 3 further illustrates an insulator 158 that may be provided on the back side 142-2 of the substrate 102 to electrically isolate the capacitor plates 162 of various capacitors 160 from the conductive contacts 152 at the back side 142-2. In FIG. 3, as well as in FIG. 4, the conductive contacts 152 are individually labeled as conductive contacts 152-1, 152-2, 152-3, and 152-4.

For the capacitor 160-1 of FIG. 3, the capacitor plates 162-1 and 162-3 are coupled to the backside power via 156-2, and the capacitor plates 162-2 and 162-4 are coupled to the backside power via 156-1. Thus, the capacitor plates 162-1 and 162-3 form the first capacitor electrode of the capacitor 160-1, while the capacitor plates 162-2 and 162-4 form the second capacitor electrode of the capacitor 160-1. For the capacitor 160-2 of FIG. 3, the capacitor plates 162-1 and 162-3 are coupled to the backside power via 156-2, and the capacitor plates 162-2 and 162-4 are coupled to the backside power via 156-3. Thus, the capacitor plates 162-1 and 162-3 form the first capacitor electrode of the capacitor 160-2, while the capacitor plates 162-2 and 162-4 form the second capacitor electrode of the capacitor 160-2. Because the first capacitor electrode of the capacitor 160-1 and the first capacitor electrode of the capacitor 160-2 are coupled to the same backside via, i.e., the backside power via 156-2, the first capacitor electrode of the capacitor 160-1 and the first capacitor electrode of the capacitor 160-2 are electrically continuous with one another. For the capacitor 160-3 of FIG. 3, the capacitor plates 162-1 and 162-3 are coupled to the backside power via 156-4, and the capacitor plates 162-2 and 162-4 are coupled to the backside power via 156-3. Thus, the capacitor plates 162-1 and 162-3 form the first capacitor electrode of the capacitor 160-3, while the capacitor plates 162-2 and 162-4 form the second capacitor electrode of the capacitor 160-3. Because the second capacitor electrode of the capacitor 160-2 and the second capacitor electrode of the capacitor 160-3 are coupled to the same backside via, i.e., the backside power via 156-3, the second capacitor electrode of the capacitor 160-2 and the second capacitor electrode of the capacitor 160-3 are electrically continuous with one another.

Any of the plurality of backside power vias 156 may include any suitable electrically conductive material, e.g., any of the materials described with reference to the electrically conductive material 118. The plurality of backside power vias 156 may be similar to the backside power via 146 in that they may be coupled to provide power and/or signals. For example, in some embodiments, the backside power via 156-1 may be coupled, through one or more of the interconnect structures 148, to one or more terminals of a first set of the III-N transistors 110. In particular, as shown in FIG. 3, the first set of the III-N transistors 110 may include two of the III-N transistors 110 sharing a first S/D region 116, and the backside power via 156-1 may be coupled to the second S/D regions 116 of these two III-N transistors 110 at one end, while the other end of the backside power via 156-1 may be coupled to the conductive contact 152-1 at the back side of the IC structure 100. Similarly, in some embodiments, other backside power vias 156, e.g., the backside power via 156-3, may be coupled, through one or more of the interconnect structures 148, to one or more terminals of a second set of the III-N transistors 110. In particular, as shown in FIG. 3, the second set of the III-N transistors 110 may include two of the III-N transistors 110, different from the two III-N transistors 110 of the first set, sharing a first S/D region 116, and the backside power via 156-3 may be coupled to the second S/D regions 116 of these two III-N transistors 110 at one end, while the other end of the backside power via 156-3 may be coupled to the conductive contact 152-3 at the back side of the IC structure 100. Furthermore, in some embodiments, any of the backside power vias 156 may be coupled to the conductive contact 154 at the front side of the IC structure 100, possibly through one or more of the interconnect structures 148 (shown in FIG. 3 with the example of the backside power via 156-2 being coupled to the conductive contact 154). As further shown in FIG. 3, the first capacitor electrode of the capacitor 160-1 and the first capacitor electrode of the capacitor 160-2 may be coupled, by means of the backside power via 156-2, to the conductive contact 152-2 at the back side of the IC structure 100, while the second capacitor electrode of the capacitor 160-2 and the second capacitor electrode of the capacitor 160-3 may be coupled, by means of the backside power via 156-3, to the conductive contact 152-3 at the back side of the IC structure 100.

FIG. 4 is a side, cross-sectional view of an IC structure 100 with III-N transistors 110, backside power vias, and magnetic cores of a magnetic inductor, in accordance with various embodiments. The IC structure 100 of FIG. 4 is similar to the IC structure 100 of FIG. 3 and, therefore, only the differences are described. As shown in FIG. 4, the IC structure 100 may include a plurality of backside power vias 156 (individually labeled as backside power vias 156-1, 156-2, 156-3, and 156-4) and one or more magnetic cores 170 (individually labeled as magnetic cores 170-1, 170-2, and 170-3). Both the backside power vias 156 and the magnetic cores 170 may extend from the back side 142-2 of the substrate 102 into the substrate 102, where an individual magnetic core 170 may be provided between two adjacent backside power vias 156. In some embodiments, the IC structure 100 of FIG. 4 may be a different portion of the IC structure 100 of FIG. 3, i.e., in some embodiments, an IC structure 100 may include both the backside capacitors 160 and the backside magnetic cores 170, along with the plurality of backside power vias 156. In other embodiments, the IC structure 100 of FIG. 4 may be an alternative to the IC structure 100 of FIG. 3. In some embodiments, the IC structure 100 of FIG. 4 may be a different portion of the IC structure 100 of FIG. 2, i.e., in some embodiments, an IC structure 100 may include both the backside thermal vias 144 of different heights and the backside magnetic cores 170 and the plurality of backside power vias 156. In other embodiments, the IC structure 100 of FIG. 4 may be an alternative to the IC structure 100 of FIG. 2. In some embodiments, the IC structure 100 of FIG. 4, the IC structure 100 of FIG. 3, and the IC structure 100 of FIG. 2 may be different portions of a single IC structure 100, i.e., in some embodiments, an IC structure 100 may include the backside thermal vias 144 of different heights, the backside capacitors 160, and the backside magnetic cores 170, along with the backside power vias 156.

Any of the magnetic cores 170 may be implemented as a structure of a suitable magnetic material, provided between a pair of adjacent backside power vias 156. In some embodiments, any of the magnetic cores 170 may include magnetic materials in the form of iron-based materials such as silicon steel (e.g., an alloy of iron and silicon, e.g., 3-4% silicon) or iron powder (e.g., finely powdered iron particles bonded with an insulator material). In some embodiments, any of the magnetic cores 170 may include magnetic materials in the form of ferrites such as ceramic compounds with iron oxide and other metal oxides (e.g., manganese, zinc, or nickel). In some embodiments, any of the magnetic cores 170 may include magnetic materials in the form of amorphous metals (e.g., rapidly cooled alloys, resulting in a non-crystalline structure) and/or layered nanocrystalline metals (e.g., metals having grain sizes in the nanometer range). In some embodiments, any of the magnetic cores 170 may include magnetic materials in the form of specialty magnetic materials such as permalloy (e.g., a nickel-iron alloy, e.g., 80% nickel, 20% iron), an enhanced version of permalloy with elements such as molybdenum added, or sendust (e.g., an alloy of iron, silicon, and aluminum). In some embodiments, any of the magnetic cores 170 may include magnetic materials in the form of soft magnetic composites (e.g., made from insulated iron powder particles) or cobalt-based alloys.

As shown in FIG. 4, the magnetic core 170-1 may be between the backside power via 156-1, coupled to the conductive contact 152-1, and the backside power via 156-2, coupled to the conductive contact 152-2. As further shown in FIG. 4, the magnetic core 170-2 may be between the backside power via 156-2 and the backside power via 156-3, coupled to the conductive contact 152-3. Furthermore, the magnetic core 170-3 may be between the backside power via 156-3 and the backside power via 156-4, coupled to the conductive contact 152-4. Although not specifically shown in FIG. 4, the conductive contact 152-1 may be electrically connected to the conductive contact 152-2, and the conductive contact 152-3 may be electrically connected to the conductive contact 152-4, which connections may be made at the back side 142-2. Furthermore, as is shown in FIG. 4, the conductive contact 152-2 may be electrically connected to the conductive contact 152-3 by means of one or more of the interconnect structures 148 at the front side 142-1 of the substrate 102. In this manner, during operation, the current may flow through the backside power vias 156 in the directions shown with arrows in each of the backside power vias 156, and, together, the plurality of the backside power vias 156 may provide a winding of a magnetic inductor, while the magnetic cores 170 may, together, form a magnetic core of the magnetic inductor.

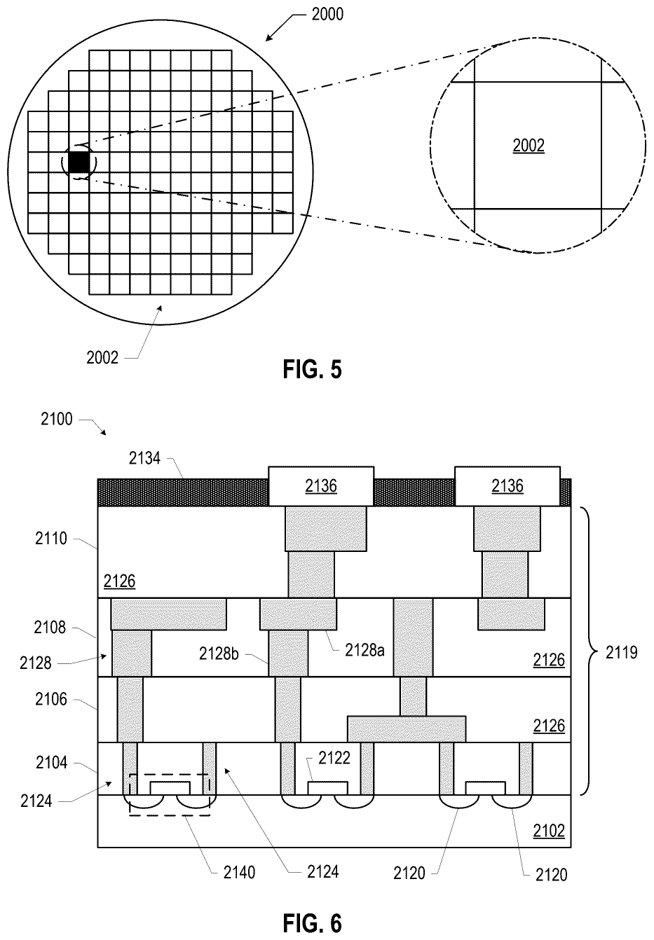

The IC structures 100 with III-N transistors and backside vias disclosed herein may include, or may be included in, any suitable electronic component or device, some examples of which are described below with reference to FIGS. 5-11.

FIG. 5 illustrates top views of a wafer and dies that may include one or more IC structures with III-N transistors and backside vias, in accordance with some embodiments. The wafer 2000 may be composed of semiconductor material and may include one or more dies 2002 having IC structures formed on a surface of the wafer 2000. Each of the dies 2002 may be a repeating unit of a semiconductor product that includes any suitable IC structure (e.g., any of the IC structures described with reference to FIGS. 1-4). After the fabrication of the semiconductor product is complete (e.g., after manufacture of one or more IC structures as described herein), the wafer 2000 may undergo a singulation process in which each of the dies 2002 is separated from one another to provide discrete “chips” of the semiconductor product. In particular, devices that include one or more IC structures as disclosed herein may take the form of the wafer 2000 (e.g., not singulated) or the form of the die 2002 (e.g., singulated). The die 2002 may include one or more III-N transistors and backside vias as described herein, and/or supporting circuitry to route electrical signals to the III-N transistors and backside vias, as well as any other IC components. In some embodiments, the wafer 2000 or the die 2002 may include a memory device (e.g., a memory device with one or more III-N transistors and backside vias), a logic device (e.g., an AND, OR, NAND, or NOR gate), or any other suitable circuit element. Multiple ones of these devices may be combined on a single die 2002. For example, a memory array formed by multiple memory devices may be formed on a same die 2002 as a processing device (e.g., the processing device 2500 of FIG. 10) or other logic that is configured to store information in the memory devices or execute instructions stored in the memory array.

FIG. 6 is a side, cross-sectional view of an IC device 2100 that may include one or more IC structures with III-N transistors and backside vias, in accordance with some embodiments. For example, any of the transistors 2140 of the IC device 2100 may be implemented as any of the III-N transistors 110, described herein. In another example, one or more of the IC devices 2100 may be included in one or more dies 2002 of FIG. 5. The IC device 2100 may be formed on a substrate 2102 (e.g., the wafer 2000 of FIG. 5) and may be included in a die (e.g., the die 2002 of FIG. 5). The substrate 2102 may take on any forms of the substrate 102, described above.

The IC device 2100 may include one or more device layers 2104 disposed on the substrate 2102. The device layer 2104 may include features of one or more transistors 2140 (e.g., MOSFETs) formed on the substrate 2102. The device layer 2104 may include, for example, one or more S/D regions 2120, a gate 2122 to control current flow in the transistors 2140 between the S/D regions 2120, and one or more S/D contacts 2124 to route electrical signals to/from the S/D regions 2120. The transistors 2140 may include additional features not depicted for the sake of clarity, such as device isolation regions, gate contacts, and the like. The transistors 2140 are not limited to the type and configuration depicted in FIG. 6 and may include a wide variety of other types and configurations such as, for example, planar transistors, non-planar transistors, or a combination of both. Planar transistors may include bipolar junction transistors (BJT), heterojunction bipolar transistors (HBT), or high-electron-mobility transistors (HEMT). Non-planar transistors may include FinFET transistors, such as double-gate transistors or tri-gate transistors, and wrap-around or gate-all-around (GAA) transistors, such as nanoribbon and nanowire transistors.

Each transistor 2140 may include a gate 2122 formed of at least two layers, a gate insulator and a gate electrode. The gate insulator of the transistor 2140 may be implemented as the gate insulator 106, while the gate electrode of the transistor 2140 may be implemented as the gate electrode material 108, described above.

The S/D regions 2120 may be formed within the substrate 2102 adjacent to the gate 2122 of each transistor 2140. The S/D regions 2120 of the transistor 2140 may be implemented as the S/D regions 116, described above.

Electrical signals, such as power and/or input/output (I/O) signals, may be routed to and/or from the devices (e.g., the transistors 2140) of the device layer 2104 through one or more interconnect layers disposed on the device layer 2104 (illustrated in FIG. 6 as interconnect layers 2106, 2108, and 2110). For example, electrically conductive features of the device layer 2104 (e.g., the gate 2122 and the S/D contacts 2124) may be electrically coupled with the interconnect structures 2128 of the interconnect layers 2106, 2108, and 2110. The one or more interconnect layers 2106, 2108, and 2110 may form a metallization stack (also referred to as an “ILD stack”) 2119 of the IC device 2100.

The interconnect structures 2128 may be arranged within the interconnect layers 2106, 2108, and 2110 to route electrical signals according to a wide variety of designs (in particular, the arrangement is not limited to the particular configuration of interconnect structures 2128 depicted in FIG. 6). Although a particular number of interconnect layers 2106, 2108, and 2110 is depicted in FIG. 6, embodiments of the present disclosure include IC devices having more or fewer interconnect layers than depicted.

In some embodiments, the interconnect structures 2128 may include conductive lines 2128a and/or conductive vias 2128b filled with an electrically conductive material such as a metal. The conductive lines 2128a may be arranged to route electrical signals in a direction of a plane that is substantially parallel with a surface of the substrate 2102 upon which the device layer 2104 is formed. For example, the conductive lines 2128a may route electrical signals in a direction in and out of the page from the perspective of FIG. 6. The conductive vias 2128b may be arranged to route electrical signals in a direction of a plane that is substantially perpendicular to the surface of the substrate 2102 upon which the device layer 2104 is formed. In some embodiments, the conductive vias 2128b may electrically couple conductive lines 2128a of different interconnect layers 2106, 2108, and 2110 together.

The interconnect layers 2106, 2108, and 2110 may include an insulator material 2126 disposed between the interconnect structures 2128, as shown in FIG. 6. In some embodiments, the insulator material 2126 disposed between the interconnect structures 2128 in different ones of the interconnect layers 2106, 2108, and 2110 may have different compositions; in other embodiments, the composition of the insulator material 2126 between different interconnect layers 2106, 2108, and 2110 may be the same.

A first interconnect layer 2106 may be formed above the device layer 2104. In some embodiments, the first interconnect layer 2106 may include conductive lines 2128a and/or conductive vias 2128b, as shown. The conductive lines 2128a of the first interconnect layer 2106 may be coupled with contacts (e.g., the S/D contacts 2124) of the device layer 2104.

A second interconnect layer 2108 may be formed above the first interconnect layer 2106. In some embodiments, the second interconnect layer 2108 may include conductive vias 2128b to couple the conductive lines 2128a of the second interconnect layer 2108 with the conductive lines 2128a of the first interconnect layer 2106. Although the conductive lines 2128a and the conductive vias 2128b are structurally delineated with a line within each interconnect layer (e.g., within the second interconnect layer 2108) for the sake of clarity, the conductive lines 2128a and the conductive vias 2128b may be structurally and/or materially contiguous (e.g., simultaneously filled during a dual-damascene process) in some embodiments.

A third interconnect layer 2110 (and additional interconnect layers, as desired) may be formed in succession on the second interconnect layer 2108 according to similar techniques and configurations described in connection with the second interconnect layer 2108 or the first interconnect layer 2106. In some embodiments, the interconnect layers that are “higher up” in the metallization stack 2119 in the IC device 2100 (i.e., farther away from the device layer 2104) may be thicker.

The IC device 2100 may include a solder resist material 2134 (e.g., polyimide or similar material) and one or more conductive contacts 2136 formed on the top one of the interconnect layers 2106, 2108, and 2110. In FIG. 6, the conductive contacts 2136 are illustrated as taking the form of bond pads. The conductive contacts 2136 may be electrically coupled with the interconnect structures 2128 and configured to route the electrical signals of the transistor(s) 2140 to other external devices. For example, solder bonds may be formed on the one or more conductive contacts 2136 to mechanically and/or electrically couple a chip including the IC device 2100 with another component (e.g., a circuit board). The IC device 2100 may include additional or alternate structures to route the electrical signals from the interconnect layers 2106, 2108, and 2110; for example, the conductive contacts 2136 may include other analogous features (e.g., posts) that route the electrical signals to external components.

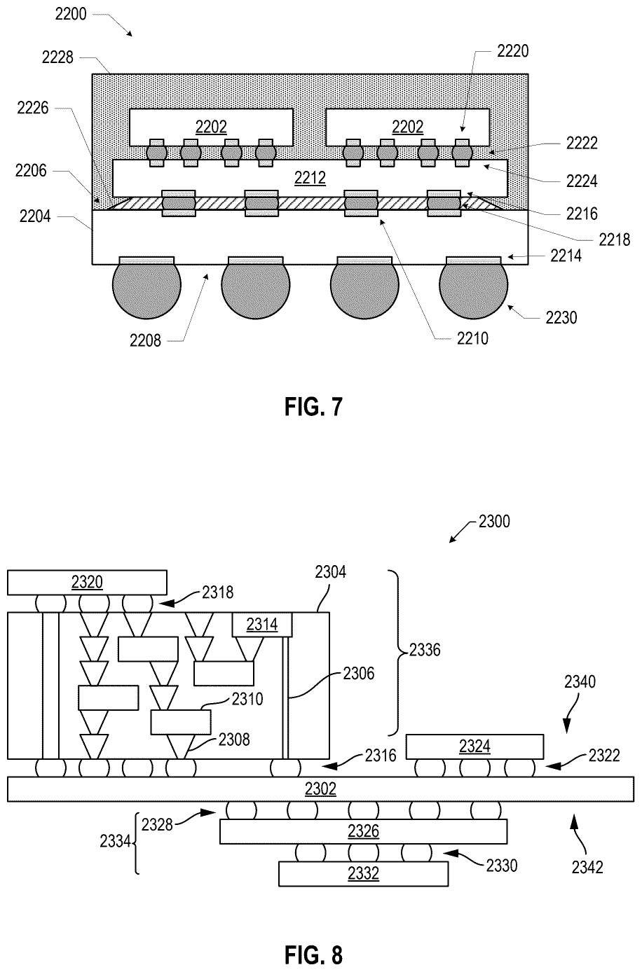

FIG. 7 is a side, cross-sectional view of an example IC package 2200 that may include one or more IC structures with III-N transistors and backside vias, in accordance with some embodiments. For example, any of the dies 2202 of the IC package 2200 may be implemented as the die 2002 of FIG. 5. In another example, any of the dies 2202 may include any of the embodiments of the IC device 2100 of FIG. 6. In embodiments in which the IC package 2200 includes multiple dies 2202, the IC package 2200 may be referred to as a multi-chip package (MCP). The dies 2202 may include circuitry to perform any desired functionality. For example, or more of the dies 2202 may be logic dies (e.g., silicon-based dies), and one or more of the dies 2202 may be memory dies (e.g., high bandwidth memory). In some embodiments, the IC package 2200 may be a system-in-package (SiP). In some embodiments, the IC package 2200 may include a photonics IC (PIC) co-packaged with an IC package. In some embodiments, the IC package 2200 may include fully integrated electronic photonics ICs (EPICs).

The IC package 2200 may include a package substrate 2204 that may be formed of a dielectric material (e.g., a ceramic, a buildup film, an epoxy film having filler particles therein, glass, an organic material, an inorganic material, combinations of organic and inorganic materials, embedded portions formed of different materials, etc.). The package substrate 2204 may have conductive pathways extending through the dielectric material between the face 2206 and the face 2208 of the package substrate 2204, or between different locations on the face 2206, and/or between different locations on the face 2208. These conductive pathways may take the form of any of the interconnect structures 2128 discussed above with reference to FIG. 6.

The package substrate 2204 may include conductive contacts 2210 that are coupled to conductive pathways (not shown) through the package substrate 2204, allowing circuitry within the dies 2202 and/or the interposer 2212 to electrically couple to various ones of the conductive contacts 2214 (or to other devices included in the package substrate 2204, not shown).

The IC package 2200 may include an interposer 2212 coupled to the package substrate 2204 via conductive contacts 2216 of the interposer 2212, first-level interconnects 2218, and the conductive contacts 2210 of the package substrate 2204. The first-level interconnects 2218 illustrated in FIG. 7 are solder bumps, but any suitable first-level interconnects 2218 may be used. In some embodiments, no interposer 2212 may be included in the IC package 2200; instead, the dies 2202 may be coupled directly to the conductive contacts 2210 at the face 2206 by first-level interconnects 2218. Generally, one or more dies 2202 may be coupled to the package substrate 2204 via any suitable structure (e.g., a silicon bridge, an organic bridge, one or more waveguides, one or more interposers, wirebonds, etc.).

The IC package 2200 may include one or more dies 2202 coupled to the interposer 2212 via conductive contacts 2220 of the dies 2202, first-level interconnects 2222, and conductive contacts 2224 of the interposer 2212. The conductive contacts 2224 may be coupled to conductive pathways (not shown) through the interposer 2212, allowing circuitry within the dies 2202 to electrically couple to various ones of the conductive contacts 2216 (or to other devices included in the interposer 2212, not shown). The first-level interconnects 2222 illustrated in FIG. 7 are solder bumps, but any suitable first-level interconnects 2222 may be used. For example, the first-level interconnects 2222 may include hybrid bonding interconnects. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

In some embodiments, an underfill material 2226 may be disposed between the package substrate 2204 and the interposer 2212 around the first-level interconnects 2218, and a mold compound 2228 may be disposed around the dies 2202 and the interposer 2212 and in contact with the package substrate 2204. In some embodiments, the underfill material 2226 may be the same as the mold compound 2228. Example materials that may be used for the underfill material 2226 and the mold compound 2228 are epoxy mold materials, as suitable. Second-level interconnects 2230 may be coupled to the conductive contacts 2214. The second-level interconnects 2230 illustrated in FIG. 7 are solder balls (e.g., for a ball grid array arrangement), but any suitable second-level interconnects 2230 may be used (e.g., pins in a pin grid array arrangement or lands in a land grid array arrangement). The second-level interconnects 2230 may be used to couple the IC package 2200 to another component, such as a circuit board (e.g., a motherboard), an interposer, or another IC package, as known in the art and as discussed below with reference to FIG. 8.

Although the IC package 2200 illustrated in FIG. 7 is a flip chip package, other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fanout (FO) package. Although two dies 2202 are illustrated in the IC package 2200 of FIG. 7, an IC package 2200 may include any desired number of dies 2202. An IC package 2200 may include additional passive components, such as surface-mount resistors, capacitors, and inductors disposed on the first face 2206 or the second face 2208 of the package substrate 2204, or on either face of the interposer 2212. More generally, an IC package 2200 may include any other active or passive components known in the art.

FIG. 8 is a side, cross-sectional view of an IC device assembly 2300 that may include one or more IC packages or other electronic components (e.g., a die) including one or more IC structures with III-N transistors and backside vias, in accordance with some embodiments. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. Any of the IC packages discussed below with reference to the IC device assembly 2300 may take the form of any of the embodiments of the IC package 2200 discussed above with reference to FIG. 7.

In some embodiments, the circuit board 2302 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 8 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302 and may include solder balls (as shown in FIG. 8), male and female portions of a socket, an adhesive, an underfill material, and/or any other suitable electrical and/or mechanical coupling structure.

The package-on-interposer structure 2336 may include an IC package 2320 coupled to a package interposer 2304 by coupling components 2318. The coupling components 2318 may take any suitable form for the application, such as the forms discussed above with reference to the coupling components 2316. Although a single IC package 2320 is shown in FIG. 8, multiple IC packages may be coupled to the package interposer 2304; indeed, additional interposers may be coupled to the package interposer 2304. The package interposer 2304 may provide an intervening substrate used to bridge the circuit board 2302 and the IC package 2320. The IC package 2320 may be or include, for example, a die (the die 2002 of FIG. 5), an IC device (e.g., the IC device 2100 of FIG. 6), or any other suitable component. Generally, the package interposer 2304 may spread a connection to a wider pitch or reroute a connection to a different connection. For example, the package interposer 2304 may couple the IC package 2320 (e.g., a die) to a set of BGA conductive contacts of the coupling components 2316 for coupling to the circuit board 2302. In the embodiment illustrated in FIG. 8, the IC package 2320 and the circuit board 2302 are attached to opposing sides of the package interposer 2304; in other embodiments, the IC package 2320 and the circuit board 2302 may be attached to a same side of the package interposer 2304. In some embodiments, three or more components may be interconnected by way of the package interposer 2304. In some embodiments, the IC package 2320 may include one or more IC structures with III-N transistors and backside vias as described herein.

In some embodiments, the package interposer 2304 may be formed as a PCB, including multiple metal layers separated from one another by layers of dielectric material and interconnected by electrically conductive vias. In some embodiments, the package interposer 2304 may be formed of an epoxy resin, a fiberglass-reinforced epoxy resin, an epoxy resin with inorganic fillers, a ceramic material, or a polymer material such as polyimide. In some embodiments, the package interposer 2304 may be formed of alternate rigid or flexible materials that may include the same materials described above for use in a semiconductor substrate, such as silicon, germanium, and other group III-V and group IV materials. The package interposer 2304 may include metal lines 2310 and vias 2308, including but not limited to TSVs 2306. The package interposer 2304 may further include embedded devices 2314, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 8 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

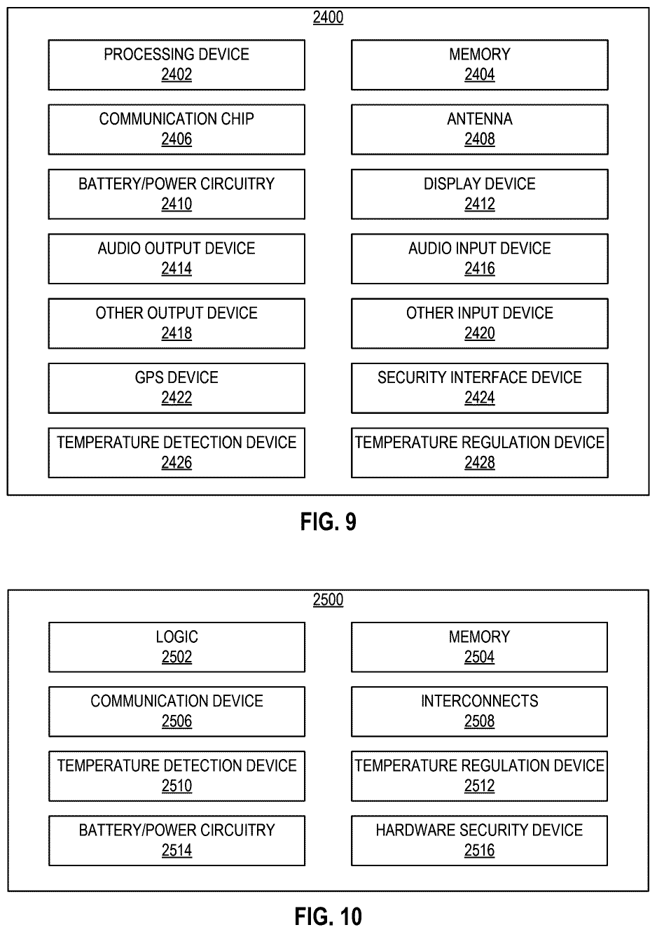

FIG. 9 is a block diagram of an example computing device 2400 that may include one or more components including one or more IC structures with III-N transistors and backside vias, in accordance with some embodiments. For example, any suitable ones of the components of the computing device 2400 may include a die (e.g., the die 2002 of FIG. 5) having one or more IC structures with III-N transistors and backside vias. Any one or more of the components of the computing device 2400 may include an IC device 2100 of FIG. 6, an IC package 2200 of FIG. 7, or an IC device assembly 2300 of FIG. 8.

A number of components are illustrated in FIG. 9 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC die.

Additionally, in various embodiments, the computing device 2400 may not include one or more of the components illustrated in FIG. 9, but the computing device 2400 may include interface circuitry for coupling to the one or more components. For example, the computing device 2400 may not include a display device 2412, but may include display device interface circuitry (e.g., a connector and driver circuitry) to which a display device 2412 may be coupled. In another set of examples, the computing device 2400 may not include an audio input device 2416 or an audio output device 2414 but may include audio input or output device interface circuitry (e.g., connectors and supporting circuitry) to which an audio input device 2416 or audio output device 2414 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), CPUs, GPUs, cryptoprocessors (specialized processors that execute cryptographic algorithms within hardware), server processors, or any other suitable processing devices. In some embodiments, the processing device 2402 may include one or more IC structures with III-N transistors and backside vias as described herein.

The computing device 2400 may include a memory 2404, which may itself include one or more memory devices such as volatile memory (e.g., DRAM), non-volatile memory (e.g., read-only memory (ROM)), flash memory, solid state memory, and/or a hard drive. In some embodiments, the memory 2404 may include memory that shares a die with the processing device 2402. This memory may be used as cache memory and may include embedded DRAM (eDRAM) or spin transfer torque magnetic random-access memory (MRAM). In some embodiments, the memory 2404 may include one or more IC structures with III-N transistors and backside vias as described herein.

In some embodiments, the computing device 2400 may include a communication chip 2406 (e.g., one or more communication chips). For example, the communication chip 2406 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2406 may implement any of a number of wireless standards or protocols, including but not limited to Institute for Electrical and Electronic Engineers (IEEE) standards including Wi-Fi (IEEE 1402.11 family), IEEE 1402.16 standards (e.g., IEEE 1402.16-2005 Amendment), Long-Term Evolution (LTE) project along with any amendments, updates, and/or revisions (e.g., advanced LTE project, ultramobile broadband (UMB) project (also referred to as “3GPP 2”), etc.). IEEE 1402.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1402.16 standards. The communication chip 2406 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2406 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2406 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2406 may operate in accordance with other wireless protocols in other embodiments. The computing device 2400 may include an antenna 2408 to facilitate wireless communications and/or to receive other wireless communications (such as AM or FM radio transmissions).

In some embodiments, the communication chip 2406 may manage wired communications, such as electrical, optical, or any other suitable communication protocols (e.g., the Ethernet). As noted above, the communication chip 2406 may include multiple communication chips. For instance, a first communication chip 2406 may be dedicated to shorter-range wireless communications such as Wi-Fi or Bluetooth, and a second communication chip 2406 may be dedicated to longer-range wireless communications such as global positioning system (GPS), EDGE, GPRS, CDMA, WiMAX, LTE, EV-DO, or others. In some embodiments, a first communication chip 2406 may be dedicated to wireless communications, and a second communication chip 2406 may be dedicated to wired communications.

The computing device 2400 may include a battery/power circuitry 2410. The battery/power circuitry 2410 may include one or more energy storage devices (e.g., batteries or capacitors) and/or circuitry for coupling components of the computing device 2400 to an energy source separate from the computing device 2400 (e.g., AC line power).

The computing device 2400 may include a display device 2412 (or corresponding interface circuitry, as discussed above). The display device 2412 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2414 (or corresponding interface circuitry, as discussed above). The audio output device 2414 may include any device that generates an audible indicator, such as speakers, headsets, or earbuds, for example.

The computing device 2400 may include an audio input device 2416 (or corresponding interface circuitry, as discussed above). The audio input device 2416 may include any device that generates a signal representative of a sound, such as microphones, microphone arrays, or digital instruments (e.g., instruments having a musical instrument digital interface (MIDI) output).

The computing device 2400 may include an other output device 2418 (or corresponding interface circuitry, as discussed above). Examples of the other output device 2418 may include an audio codec, a video codec, a printer, a wired or wireless transmitter for providing information to other devices, or an additional storage device.

The computing device 2400 may include an other input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may include a GPS device 2422 (or corresponding interface circuitry, as discussed above). The GPS device 2422 may be in communication with a satellite-based system and may receive a location of the computing device 2400, as known in the art.

The computing device 2400 may include a security interface device 2424. The security interface device 2424 may include any device that provides security features for the computing device 2400 or for any individual components therein (e.g., for the processing device 2402 or for the memory 2404). Examples of security features may include authorization, access to digital certificates, access to items in keychains, etc. Examples of the security interface device 2424 may include a software firewall, a hardware firewall, an antivirus, a content filtering device, or an intrusion detection device.

In some embodiments, the computing device 2400 may include a temperature detection device 2426 and a temperature regulation device 2428.

The temperature detection device 2426 may include any device capable of determining temperatures of the computing device 2400 or of any individual components therein (e.g., temperatures of the processing device 2402 or of the memory 2404). In various embodiments, the temperature detection device 2426 may be configured to determine temperatures of an object (e.g., the computing device 2400, components of the computing device 2400, devices coupled to the computing device, etc.), temperatures of an environment (e.g., a data center that includes, is controlled by, or otherwise associated with the computing device 2400), and so on. The temperature detection device 2426 may include one or more temperature sensors. Different temperature sensors of the temperature detection device 2426 may have different locations within and around the computing device 2400. A temperature sensor may generate data (e.g., digital data) representing detected temperatures and provide the data to another device, e.g., to the temperature regulation device 2428, the processing device 2402, the memory 2404, etc. In some embodiments, a temperature sensor of the temperature detection device 2426 may be turned on or off, e.g., by the processing device 2402 or an external system. The temperature sensor detects temperatures when it is on and does not detect temperatures when it is off. In other embodiments, a temperature sensor of the temperature detection device 2426 may detect temperatures continuously and automatically or detect temperatures at predefined times or at times triggered by an event associated with the computing device 2400 or any components therein.

The temperature regulation device 2428 may include any device configured to change (e.g., decrease) temperatures, e.g., based on one or more target temperatures and/or based on temperature measurements performed by the temperature detection device 2426. A target temperature may be a preferred temperature. A target temperature may depend on a setting in which the computing device 2400 operates. In some embodiments, the target temperature may be 200 Kelvin degrees or lower. In some embodiments, the target temperature may be 20 Kelvin degrees or lower, or 5 Kelvin degrees or lower. Target temperatures for different objects and different environments of, or associated with, the computing device 2400 can be different. In some embodiments, cooling provided by the temperature regulation device 2428 may be a multi-stage process with temperatures ranging from room temperature to 4K or lower.

In some embodiments, the temperature regulation device 2428 may include one or more cooling devices. Different cooling device may have different locations within and around the computing device 2400. A cooling device of the temperature regulation device 2428 may be associated with one or more temperature sensors of the temperature detection device 2426 and may be configured to operate based on temperatures detected the temperature sensors. For instance, a cooling device may be configured to determine whether a detected ambient temperature is above the target temperature or whether the detected ambient temperature is higher than the target temperature by a predetermined value or determine whether any other temperature-related condition associated with the temperature of the computing device 2400 is satisfied. In response to determining that one or more temperature-related condition associated with the temperature of the computing device 2400 are satisfied (e.g., in response to determining that the detected ambient temperature is above the target temperature), a cooling device may trigger its cooling mechanism and start to decrease the ambient temperature. Otherwise, the cooling device does not trigger any cooling. A cooling device of the temperature regulation device 2428 may operate with various cooling mechanisms, such as evaporation cooling, radiation cooling, conduction cooling, convection cooling, other cooling mechanisms, or any combination thereof. A cooling device of the temperature regulation device 2428 may include a cooling agent, such as a water, oil, liquid nitrogen, liquid helium, etc. In some embodiments, the temperature regulation device 2428 may be, for example, a dilution refrigerator, a helium-3 refrigerator, or a liquid helium refrigerator. In some embodiments, the temperature regulation device 2428 or any portions thereof (e.g., one or more of the individual cooling devices) may be connected to the computing device 2400 in close proximity (e.g., less than about 1 meter) or may be provided in a separate enclosure where a dedicated heat exchanger (e.g., a compressor, a heating, ventilation, and air conditioning (HVAC) system, liquid helium, liquid nitrogen, etc.) may reside.

By maintaining the target temperatures, the energy consumption of the computing device 2400 (or components thereof) can be reduced, while the computing efficiency may be improved. For example, when the computing device 2400 (or components thereof) operates at lower temperatures, energy dissipation (e.g., heat dissipation) may be reduced. Further, energy consumed by semiconductor components (e.g., energy needed for switching transistors of any of the components of the computing device 2400) can also be reduced. Various semiconductor materials may have lower resistivity and/or higher mobility at lower temperatures. That way, the electrical current per unit supply voltage may be increased by lowering temperatures. Conversely, for the same current that would be needed, the supply voltage may be lowered by lowering temperatures. As energy corelates to the supply voltage, the energy consumption of the semiconductor components may lower too. In some implementations, the energy savings due to reducing heat dissipation and reducing energy consumed by semiconductor components of the computing device or components thereof may outweigh (sometimes significantly outweigh) the costs associated with energy needed for cooling.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

FIG. 10 is a block diagram of an example processing device 2500 that may include one or more IC structures with III-N transistors and backside vias as described herein. For example, any suitable ones of the components of the processing device 2500 may include a die (e.g., the die 2002 of FIG. 5) having one or more IC structures with III-N transistors and backside vias as described herein, Any one or more of the components of the processing device 2500 may include an IC device 2100 of FIG. 6, an IC package 2200 of FIG. 7, or an IC device assembly 2300 of FIG. 8. Any one or more of the components of the processing device 2500 may include, or be included in, a computing device 2400 of FIG. 9; for example, the processing device 2500 may be the processing device 2402 of the computing device 2400.

A number of components are illustrated in FIG. 10 as included in the processing device 2500, but any one or more of these components may be omitted or duplicated, as suitable for the application. In some embodiments, some or all of the components included in the processing device 2500 may be attached to one or more motherboards. In some embodiments, some or all of these components are fabricated on a single SoC die or coupled to a single base, e.g., to a single carrier substrate.

Additionally, in various embodiments, the processing device 2500 may not include one or more of the components illustrated in FIG. 10, but the processing device 2500 may include interface circuitry for coupling to the one or more components. For example, the processing device 2500 may not include a memory 2504, but may include display device interface circuitry (e.g., a connector and driver circuitry) to which a memory 2504 may be coupled.

The processing device 2500 may include logic circuitry 2502 (e.g., one or more circuits configured to implement logic/compute functionality). Examples of such circuits include ICs implementing one or more of input/output (I/O) functions, arithmetic operations, pipelining of data, etc.

In some embodiments, the logic circuitry 2502 may include one or more circuits responsible for read/write operations with respect to the data stored in the memory 2504. To that end, the logic circuitry 2502 may include one or more I/O ICs configured to control access to data stored in the memory 2504.

In some embodiments, the logic circuitry 2502 may include one or more high-performance compute dies, configured to perform various operations with respect to data stored in the memory 2504 (e.g., arithmetic and logic operations, pipelining of data from one or more memory dies of the memory 2504, and possibly also data from external devices/chips). In some embodiments, the logic circuitry 2502 may be configured to only control I/O access to data but not perform any operations on the data. In some embodiments, the logic circuitry 2502 may implement ICs configured to implement I/O control of data stored in the memory 2504, assemble data from the memory 2504 for transport (e.g., transport over a central bus) to devices/chips that are either internal or external to the processing device 2500, etc. In some embodiments, the logic circuitry 2502 may not be configured to perform any operations on the data besides I/O and assembling for transport to the memory 2504.

The processing device 2500 may include a memory 2504, which may include one or more ICs configure to implement memory circuitry (e.g., ICs implementing one or more of memory devices, memory arrays, control logic configured to control the memory devices and arrays, etc.). In some embodiments, the memory 2504 may be implemented substantially as described above with reference to the memory 2404 (FIG. 9). In some embodiments, the memory 2504 may be a designated device configured to provide storage functionality for the components of the processing device 2500 (e.g., local), while the memory 2404 may be configured to provide system-level storage functionality for the entire computing device 2400 (e.g., global). In some embodiments, the memory 2504 may include memory that shares a die with the logic circuitry 2502.

The processing device 2500 may include a communication device 2506, which may be implemented substantially as described above with reference to the communication chip 2406 (FIG. 9). In some embodiments, the communication device 2506 may be a designated device configured to provide communication functionality for the components of the processing device 2500 (e.g., local), while the communication chip 2406 may be configured to provide system-level communication functionality for the entire computing device 2400 (e.g., global).

The processing device 2500 may include interconnects 2508, which may include any element or device that includes an electrically conductive material for providing electrical connectivity to one or more components of, or associated with, a processing device 2500 or/and between various such components. Examples of the interconnects 2508 include conductive lines/wires (also sometimes referred to as “lines” or “metal lines” or “trenches”) and conductive vias (also sometimes referred to as “vias” or “metal vias”). In some embodiments, the interconnects 2508 may be implemented as the interconnect structures 2128 of FIG. 6, described above.

The processing device 2500 may include a temperature detection device 2510 which may be implemented substantially as described above with reference to the temperature detection device 2426 of FIG. 9 but configured to determine temperatures on a more local scale, e.g., of the processing device 2500 of components thereof. In some embodiments, the temperature detection device 2510 may be a designated device configured to provide temperature detection functionality for the components of the processing device 2500 (e.g., local), while the temperature detection device 2426 may be configured to provide system-level temperature detection functionality for the entire computing device 2400 (e.g., global).

The processing device 2500 may include a temperature regulation device 2512 which may be implemented substantially as described above with reference to the temperature regulation device 2428 of FIG. 9 but configured to regulate temperatures on a more local scale, e.g., of the processing device 2500 of components thereof. In some embodiments, the temperature regulation device 2512 may be a designated device configured to provide temperature regulation functionality for the components of the processing device 2500 (e.g., local), while the temperature regulation device 2428 may be configured to provide system-level temperature regulation functionality for the entire computing device 2400 (e.g., global).

The processing device 2500 may include a battery/power circuitry 2514 which may be implemented substantially as described above with reference to the battery/power circuitry 2410 of FIG. 9. In some embodiments, the battery/power circuitry 2514 may be a designated device configured to provide battery/power functionality for the components of the processing device 2500 (e.g., local), while the battery/power circuitry 2410 may be configured to provide system-level battery/power functionality for the entire computing device 2400 (e.g., global).

The processing device 2500 may include a hardware security device 2516 which may be implemented substantially as described above with reference to the security interface device 2424 of FIG. 9. In some embodiments, the hardware security device 2516 may be a physical computing device configured to safeguard and manage digital keys, perform encryption and decryption functions for digital signatures, authentication, and other cryptographic functions. In some embodiments, the hardware security device 2516 may include one or more secure cryptoprocessors chips.

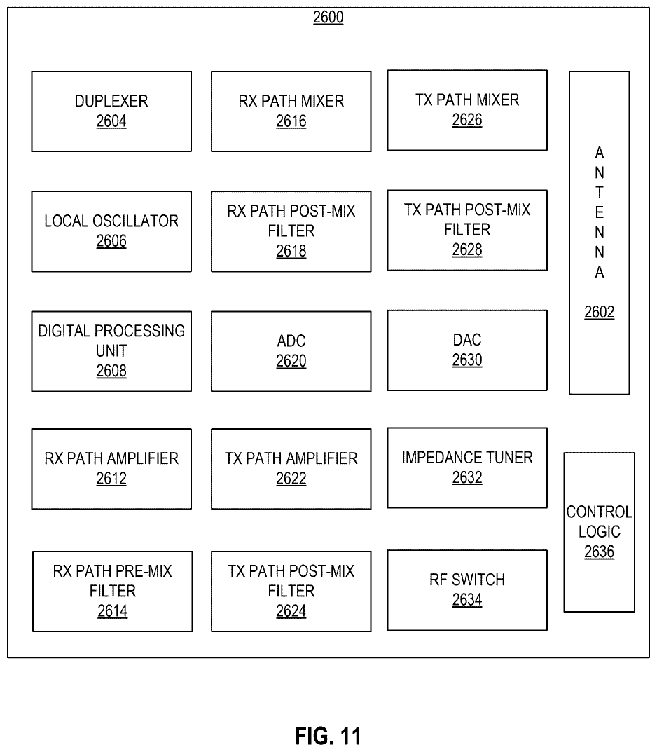

FIG. 11 is a block diagram of an example RF device 2600 that may include one or more IC structures with III-N transistors and backside vias in accordance with any of the embodiments disclosed herein. For example, any suitable ones of the components of the RF device 2600 may include a die (e.g., the die 2002 of FIG. 5) having one or more IC structures with III-N transistors and backside vias as described herein. Any one or more of the components of the RF device 2600 (e.g., an RF switch 2634) may include an IC structure 100 of any of FIGS. 1-4, an IC device 2100 of FIG. 6, an IC package 2200 of FIG. 7, or an IC device assembly 2300 of FIG. 8. In still other embodiments, the RF device 2600 may further include any of the components described above with reference to FIG. 9 or FIG. 10, such as, but not limited to, the processing device 2402, the battery/power circuitry 2410 or the battery/power circuitry 2514, the memory 2404 or the logic circuitry 2502, and various input and output devices as discussed above with reference to FIG. 9.

In general, the RF device 2600 may be any device or system that may support wireless transmission and/or reception of signals in the form of electromagnetic waves in the RF range of approximately 3 kiloHertz (kHz) to 300 gigaHertz (GHz). In some embodiments, the RF device 2600 may be used for wireless communications, e.g., in a BS or a UE device of any suitable cellular wireless communications technology, such as GSM, WCDMA, or LTE. In a further example, the RF device 2600 may be used as, or in, a BS or a UE device of a millimeter-wave wireless technology such as fifth generation (5G) wireless (e.g., high-frequency/short wavelength spectrum, with frequencies in the range between about 20 and 60 GHz, corresponding to wavelengths in the range between about 5 and 15 millimeters). In yet another example, the RF device 2600 may be used for wireless communications using Wi-Fi technology (e.g., a frequency band of 2.4 GHz, corresponding to a wavelength of about 12 cm, or a frequency band of 5.8 GHz, corresponding to a wavelength of about 5 cm). For example, the RF device 2600 may be included in a Wi-Fi-enabled device such as a desktop, a laptop, a video game console, a smart phone, a tablet, a smart TV, a digital audio player, a car, a printer, etc. In some implementations, a Wi-Fi-enabled device may be a node (e.g., a smart sensor) in a smart system configured to communicate data with other nodes. In another example, the RF device 2600 may be used for wireless communications using Bluetooth technology (e.g., a frequency band from about 2.4 to about 2.485 GHz, corresponding to a wavelength of about 12 cm). In other embodiments, the RF device 2600 may be used for transmitting and/or receiving RF signals for purposes other than communication (e.g., in an automotive radar system, or in medical applications such as magnetic resonance imaging (MRI)).

In various embodiments, the RF device 2600 may be included in frequency-division duplex (FDD) or time-domain duplex (TDD) variants of frequency allocations that may be used in a cellular network. In an FDD system, the uplink (i.e., RF signals transmitted from the UE devices to a BS) and the downlink (i.e., RF signals transmitted from the BS to the US devices) may use separate frequency bands at the same time. In a TDD system, the uplink and the downlink may use the same frequencies but at different times.

A number of components are illustrated in FIG. 11 as included in the RF device 2600, but any one or more of these components may be omitted or duplicated, as suitable for the application. For example, in some embodiments, the RF device 2600 may be an RF device supporting both of wireless transmission and reception of RF signals (e.g., an RF transceiver), in which case it may include both the components of what is referred to herein as a transmit (TX) path and the components of what is referred to herein as a receive (RX) path. However, in other embodiments, the RF device 2600 may be an RF device supporting only wireless reception (e.g., an RF receiver), in which case it may include the components of the RX path, but not the components of the TX path; or the RF device 2600 may be an RF device supporting only wireless transmission (e.g., an RF transmitter), in which case it may include the components of the TX path, but not the components of the RX path.

In some embodiments, some or all of the components included in the RF device 2600 may be attached to one or more motherboards. In various embodiments, the RF device 2600 may not include one or more of the components illustrated in FIG. 11, but the RF device 2600 may include interface circuitry for coupling to the one or more components. For example, the RF device 2600 may not include an antenna 2602, but may include antenna interface circuitry (e.g., a matching circuitry, a connector and driver circuitry) to which an antenna 2602 may be coupled. In another set of examples, the RF device 2600 may not include a digital processing unit 2608 or a local oscillator 2606, but may include device interface circuitry (e.g., connectors and supporting circuitry) to which a digital processing unit 2608 or a local oscillator 2606 may be coupled.

As shown in FIG. 11, the RF device 2600 may include an antenna 2602, a duplexer 2604, a local oscillator 2606, and a digital processing unit 2608. As also shown in FIG. 11, the RF device 2600 may include an RX path that may include an RX path amplifier 2612, an RX path pre-mix filter 2614, a RX path mixer 2616, an RX path post-mix filter 2618, and an analog-to-digital converter (ADC) 2620. As further shown in FIG. 11, the RF device 2600 may include a TX path that may include a TX path amplifier 2622, a TX path post-mix filter 2624, a TX path mixer 2626, a TX path pre-mix filter 2628, and a digital-to-analog converter (DAC) 2630. Still further, the RF device 2600 may further include an impedance tuner 2632, an RF switch 2634, and control logic 2636. In various embodiments, the RF device 2600 may include multiple instances of any of the components shown in FIG. 11. In some embodiments, the RX path amplifier 2612, the TX path amplifier 2622, the duplexer 2604, and the RF switch 2634 may be considered to form, or be a part of, an RF front-end (FE) of the RF device 2600. In some embodiments, the RX path amplifier 2612, the TX path amplifier 2622, the duplexer 2604, and the RF switch 2634 may be considered to form, or be a part of, an RF FE of the RF device 2600. In some embodiments, the RX path mixer 2616 and the TX path mixer 2626 (possibly with their associated pre-mix and post-mix filters shown in FIG. 11) may be considered to form, or be a part of, an RF transceiver of the RF device 2600, or of an RF receiver or an RF transmitter if only RX path or TX path components, respectively, are included in the RF device 2600). In some embodiments, the RF device 2600 may further include one or more control logic elements/circuits, shown in FIG. 11 as control logic 2636 (providing, for example, an RF FE control interface). The control logic 2636 may be used to enhance control of complex RF system environment, support implementation of envelope tracking techniques, reduce dissipated power, etc.

The antenna 2602 may be configured to wirelessly transmit and/or receive RF signals in accordance with any wireless standards or protocols, e.g., Wi-Fi, LTE, or GSM, as well as any other wireless protocols that are designated as 3G, 4G, 5G, and beyond. If the RF device 2600 is an FDD transceiver, the antenna 2602 may be configured for concurrent reception and transmission of communication signals in separate, e.g., non-overlapping and non-continuous, bands of frequencies, e.g., in bands having a separation of, e.g., 20 MHz from one another. If the RF device 2600 is a TDD transceiver, the antenna 2602 may be configured for sequential reception and transmission of communication signals in bands of frequencies that may be the same, or overlapping for TX and RX paths. In some embodiments, the RF device 2600 may be a multi-band RF device, in which case the antenna 2602 may be configured for concurrent reception of signals having multiple RF components in separate frequency bands and/or configured for concurrent transmission of signals having multiple RF components in separate frequency bands. In such embodiments, the antenna 2602 may be a single wide-band antenna or a plurality of band-specific antennas (e.g., a plurality of antennas each configured to receive and/or transmit signals in a specific band of frequencies). In various embodiments, the antenna 2602 may include a plurality of antenna elements, e.g., a plurality of antenna elements forming a phased antenna array (i.e., a communication system or an array of antennas that may use a plurality of antenna elements and phase shifting to transmit and receive RF signals). Compared to a single-antenna system, a phased antenna array may offer advantages such as increased gain, ability of directional steering, and simultaneous communication. In some embodiments, the RF device 2600 may include more than one antenna 2602 to implement antenna diversity. In some such embodiments, the RF switch 2634 may be deployed to switch between different antennas.

An output of the antenna 2602 may be coupled to the input of the duplexer 2604. The duplexer 2604 may be any suitable component configured for filtering multiple signals to allow for bidirectional communication over a single path between the duplexer 2604 and the antenna 2602. The duplexer 2604 may be configured for providing RX signals to the RX path of the RF device 2600 and for receiving TX signals from the TX path of the RF device 2600.

The RF device 2600 may include one or more local oscillators 2606, configured to provide local oscillator signals that may be used for downconversion of the RF signals received by the antenna 2602 and/or upconversion of the signals to be transmitted by the antenna 2602.

The RF device 2600 may include the digital processing unit 2608, which may include one or more processing devices. In some embodiments, the digital processing unit 2608 may be implemented as the processing device 2402 of FIG. 9, descriptions of which are provided above. The digital processing unit 2608 may be configured to perform various functions related to digital processing of the RX and/or TX signals. Examples of such functions include, but are not limited to, decimation/downsampling, error correction, digital downconversion or upconversion, DC offset cancellation, automatic gain control, etc. Although not shown in FIG. 11, in some embodiments, the RF device 2600 may further include a memory device (e.g., the memory 2404 described above with reference to FIG. 9) configured to cooperate with the digital processing unit 2608.

Turning to the details of the RX path that may be included in the RF device 2600, the RX path amplifier 2612 may include a low noise amplifier (LNA). An input of the RX path amplifier 2612 may be coupled to an antenna port (not shown) of the antenna 2602, e.g., via the duplexer 2604. The RX path amplifier 2612 may amplify the RF signals received by the antenna 2602.

An output of the RX path amplifier 2612 may be coupled to an input of the RX path pre-mix filter 2614, which may be a harmonic or band-pass (e.g., low-pass) filter, configured to filter received RF signals that have been amplified by the RX path amplifier 2612.

An output of the RX path pre-mix filter 2614 may be coupled to an input of the RX path mixer 2616, also referred to as a downconverter. The RX path mixer 2616 may include two inputs and one output. A first input may be configured to receive the RX signals, which may be current signals, indicative of the signals received by the antenna 2602 (e.g., the first input may receive the output of the RX path pre-mix filter 2614). A second input may be configured to receive local oscillator signals from one of the local oscillators 2606. The RX path mixer 2616 may then mix the signals received at its two inputs to generate a downconverted RX signal, provided at an output of the RX path mixer 2616. As used herein, downconversion refers to a process of mixing a received RF signal with a local oscillator signal to generate a signal of a lower frequency. In particular, the RX path mixer (e.g., downconverter) 2616 may be configured to generate the sum and/or the difference frequency at the output port when two input frequencies are provided at the two input ports. In some embodiments, the RF device 2600 may implement a direct-conversion receiver (DCR), also known as homodyne, synchrodyne, or zero-intermediate frequency (IF) receiver, in which case the RX path mixer 2616 may be configured to demodulate the incoming radio signals using local oscillator signals whose frequency is identical to, or very close to the carrier frequency of the radio signal. In other embodiments, the RF device 2600 may make use of downconversion to an IF. IFs may be used in superheterodyne radio receivers, in which a received RF signal is shifted to an IF, before the final detection of the information in the received signal is done. Conversion to an IF may be useful for several reasons. For example, when several stages of filters are used, they can all be set to a fixed frequency, which makes them easier to build and to tune. In some embodiments, the RX path mixer 2616 may include several such stages of IF conversion.

Although a single RX path mixer 2616 is shown in the RX path of FIG. 11, in some embodiments, the RX path mixer 2616 may be implemented as a quadrature downconverter, in which case it would include a first RX path mixer and a second RX path mixer. The first RX path mixer may be configured for performing downconversion to generate an in-phase (I) downconverted RX signal by mixing the RX signal received by the antenna 2602 and an in-phase component of the local oscillator signal provided by the local oscillator 2606. The second RX path mixer may be configured for performing downconversion to generate a quadrature (Q) downconverted RX signal by mixing the RX signal received by the antenna 2602 and a quadrature component of the local oscillator signal provided by the local oscillator 2606 (the quadrature component is a component that is offset, in phase, from the in-phase component of the local oscillator signal by 90 degrees). The output of the first RX path mixer may be provided to a I-signal path, and the output of the second RX path mixer may be provided to a Q-signal path, which may be substantially 90 degrees out of phase with the I-signal path.

The output of the RX path mixer 2616 may, optionally, be coupled to the RX path post-mix filter 2618, which may be low-pass filters. In case the RX path mixer 2616 is a quadrature mixer that implements the first and second mixers as described above, the in-phase and quadrature components provided at the outputs of the first and second mixers respectively may be coupled to respective individual first and second RX path post-mix filters included in the RX path post-mix filter 2618.

The ADC 2620 may be configured to convert the mixed RX signals from the RX path mixer 2616 from the analog to the digital domain. The ADC 2620 may be a quadrature ADC that, similar to the RX path mixer 2616, may include two ADCs, configured to digitize the downconverted RX path signals separated in in-phase and quadrature components. The output of the ADC 2620 may be provided to the digital processing unit 2608, configured to perform various functions related to digital processing of the RX signals so that information encoded in the RX signals can be extracted.

Turning to the details of the TX path that may be included in the RF device 2600, the digital signal to later be transmitted (TX signal) by the antenna 2602 may be provided, from the digital processing unit 2608, to the DAC 2630. Similar to the ADC 2620, the DAC 2630 may include two DACs, configured to convert, respectively, digital I-and Q-path TX signal components to analog form.

Optionally, the output of the DAC 2630 may be coupled to the TX path pre-mix filter 2628, which may be a band-pass (e.g., low-pass) filter (or a pair of band-pass, e.g., low-pass, filters, in case of quadrature processing) configured to filter out, from the analog TX signals output by the DAC 2630, the signal components outside of the desired band. The digital TX signals may then be provided to the TX path mixer 2626, which may also be referred to as an upconverter. Similar to the RX path mixer 2616, the TX path mixer 2626 may include a pair of TX path mixers, for in-phase and quadrature component mixing. Similar to the first and second RX path mixers that may be included in the RX path, each of the TX path mixers of the TX path mixer 2626 may include two inputs and one output. A first input may receive the TX signal components, converted to the analog form by the respective DAC 2630, which are to be upconverted to generate RF signals to be transmitted. The first TX path mixer may generate an in-phase (I) upconverted signal by mixing the TX signal component converted to analog form by the DAC 2630 with the in-phase component of the TX path local oscillator signal provided from the local oscillator 2606 (in various embodiments, the local oscillator 2606 may include a plurality of different local oscillators, or be configured to provide different local oscillator frequencies for the RX path mixer 2616 in the RX path and the TX path mixer 2626 in the TX path). The second TX path mixer may generate a quadrature phase (Q) upconverted signal by mixing the TX signal component converted to analog form by the DAC 2630 with the quadrature component of the TX path local oscillator signal. The output of the second TX path mixer may be added to the output of the first TX path mixer to create a real RF signal. A second input of each of the TX path mixers may be coupled the local oscillator 2606.

Optionally, the RF device 2600 may include the TX path post-mix filter 2624, configured to filter the output of the TX path mixer 2626.

As noted above, the TX path amplifier 2622 may be a power amplifier (PA), configured to amplify the upconverted RF signal before providing it to the antenna 2602 for transmission

In various embodiments, any of the RX path pre-mix filter 2614, the RX path post-mix filter 2618, the TX path post-mix filter 2624, and the TX path pre-mix filter 2628 may be implemented as RF filters. In some embodiments, each of such RF filters may include one or more resonators (e.g., AWRs, film bulk acoustic resonators (FBARs), Lamb wave resonators, and/or contour-wave resonators), arranged in any suitable manner (e.g., in a ladder configuration). In some embodiments, an RF filter may be implemented as a plurality of RF filters, or a filter bank. A filter bank may include a plurality of RF resonators that may be coupled to a switch (e. g., the RF switch 2634) configured to selectively switch any one of the plurality of RF resonators on and off (e.g., activate any one of the plurality of RF resonators), in order to achieve desired filtering characteristics of the filter bank (e.g., in order to program the filter bank). For example, such a filter bank may be used to switch between different RF frequency ranges when the RF device 2600 is, or is included in, a BS or in a UE device. In another example, such a filter bank may be programmable to suppress TX leakage on the different duplex distances.

The impedance tuner 2632 may include any suitable circuitry, configured to match the input and output impedances of the different RF circuitries to minimize signal losses in the RF device 2600. For example, the impedance tuner 2632 may include an antenna impedance tuner. Being able to tune the impedance of the antenna 2602 may be particularly advantageous because antenna's impedance is a function of the environment that the RF device 2600 is in, e.g., antenna's impedance changes depending on, e.g., if the antenna is held in a hand, placed on a car roof, etc.

As described above, the RF switch 2634 may be a device configured to route high-frequency signals through transmission paths in order to selectively switch between a plurality of instances of any one of the components shown in FIG. 11 (e.g., to achieve desired behavior and characteristics of the RF device 2600). In some embodiments, an RF switch 2634 may be used to switch between different antennas 2602. In other embodiments, an RF switch may be used to switch between a plurality of RF resonators (e.g., by selectively switching RF resonators on and off) of any of the filters included in the RF device 2600. Typically, an RF system may include a plurality of such RF switches.

The RF device 2600 provides a simplified version and, in further embodiments, other components not specifically shown in FIG. 11 may be included. For example, the RX path of the RF device 2600 may include a current-to-voltage amplifier between the RX path mixer 2616 and the ADC 2620, which may be configured to amplify and convert the downconverted signals to voltage signals. In another example, the RX path of the RF device 2600 may include a balun transformer for generating balanced signals. In yet another example, the RF device 2600 may further include a clock generator, which may include a suitable phase-lock loop (PLL), configured to receive a reference clock signal and use it to generate a different clock signal that may then be used for timing the operation of the ADC 2620, the DAC 2630, and/or that may also be used by the local oscillator 2606 to generate the local oscillator signals to be used in the RX path or the TX path.

The following paragraphs provide examples of various ones of the embodiments disclosed herein.
Example 1 provides an IC structure that includes a substrate having a first side and a second side; a semiconductor material over the first side of the substrate, the semiconductor material including gallium and nitrogen; a first conductive via; and a second conductive via, in which: the first conductive via and the second conductive via extend from the second side of the substrate to the first side of the substrate (i.e., extending through the substrate) and into the semiconductor material, and a distance between the second side of the substrate and an end of the first conductive via in the semiconductor material is different from a distance between the second side of the substrate and an end of the second conductive via in the semiconductor material (i.e., the first and second conductive vias have different heights).
Example 2 provides the IC structure according to example 1, in which the first conductive via and the second conductive via are electrically isolated from all signal and power pathways in the IC structure.
Example 3 provides the IC structure according to examples 1 or 2, in which at least one of the first conductive via and the second conductive via is electrically connected to a ground pathway.
Example 4 provides the IC structure according to any one of the preceding examples, in which: the semiconductor material is a first semiconductor material, the IC structure further includes a second semiconductor material over the first side of the substrate, the second semiconductor material including aluminum and nitrogen, the second semiconductor material is between the substrate and the first semiconductor material, and the first conductive via and the second conductive via extend through the second semiconductor material.
Example 5 provides the IC structure according to example 4, in which a thermal conductivity of the second semiconductor material is lower than a thermal conductivity of the first semiconductor material.
Example 6 provides the IC structure according to examples 4 or 5, in which: the IC structure further includes a third semiconductor material over the first side of the substrate, the third semiconductor material including aluminum and nitrogen and having a different material composition than the second semiconductor material, the third semiconductor material is between the substrate and the second semiconductor material, the second semiconductor material is between the third semiconductor material and the first semiconductor material, and the first conductive via and the second conductive via extend through the third semiconductor material.
Example 7 provides the IC structure according to any one of the preceding examples, further including a transistor over the first side of the substrate, in which a portion of the semiconductor material is a channel region of the transistor.
Example 8 provides the IC structure according to example 7, further including a layer of an insulator material over the semiconductor material; and a third conductive via, in which: the third conductive via extends from the second side of the substrate to the first side of the substrate (i.e., extending through the substrate), through the semiconductor material, and into the layer of the insulator material, and the third conductive via is electrically connected to a terminal of the transistor.
Example 9 provides the IC structure according to example 7, further including a layer of an insulator material over the semiconductor material; and a third conductive via, in which: the third conductive via extends from the second side of the substrate to the first side of the substrate (i.e., extending through the substrate), through the semiconductor material, and into the layer of the insulator material, and the third conductive via is electrically connected to a signal pathway or a power pathway in the IC structure.
Example 10 provides the IC structure according to any one of the preceding examples, further including a capacitor extending from the second side of the substrate into the substrate.
Example 11 provides the IC structure according to example 10, further including a layer of an insulator material over the semiconductor material; a third conductive via; and a fourth conductive via, in which: the third conductive via and the fourth conductive via extend from the second side of the substrate to the first side of the substrate (i.e., extending through the substrate), through the semiconductor material, and into the layer of the insulator material, the third conductive via is electrically connected to a first capacitor electrode of the capacitor, and the fourth conductive via is electrically connected to a second capacitor electrode of the capacitor.
Example 12 provides the IC structure according to example 11, further including a transistor over the first side of the substrate, in which: a portion of the semiconductor material is a channel region of the transistor, and the third conductive via is electrically connected to a terminal of the transistor.
Example 13 provides the IC structure according to any one of the preceding examples, further including a magnetic inductor including a structure of a magnetic material (a magnetic core of the magnetic inductor), in which the structure of the magnetic material extends from the second side of the substrate into the substrate.
Example 14 provides the IC structure according to example 13, further including a layer of an insulator material over the semiconductor material; a third conductive via; a fourth conductive via; and a conductive interconnect in the layer of the insulator material, in which: the third conductive via and the fourth conductive via extend from the second side of the substrate to the first side of the substrate (i.e., extending through the substrate), through the semiconductor material, and into the layer of the insulator material, the conductive interconnect is electrically connected to the third conductive via and the fourth conductive via (e.g., the conductive interconnect is used to electrically connect these two conductive vias to one another), and the structure of the magnetic material is between the third conductive via and the fourth conductive via.
Example 15 provides the IC structure according to examples 13 or 14, further including a transistor over the first side of the substrate, in which: a portion of the semiconductor material is a channel region of the transistor, and at least a portion of the transistor is vertically stacked above the structure of the magnetic material.
Example 16 provides the IC structure according to any one of examples 13-15, further including a capacitor extending from the second side of the substrate into the substrate.
Example 17 provides an IC structure that includes a substrate having a first side and a second side; a semiconductor material over the first side of the substrate, the semiconductor material including gallium and nitrogen; an insulator material over the semiconductor material; a transistor over the first side of the substrate, in which a portion of the semiconductor material is a channel region of the transistor; a first conductive via; a second conductive via; and a capacitor extending from the second side of the substrate into the substrate, in which: the first conductive via and the second conductive via extend from the second side of the substrate to the first side of the substrate (i.e., extending through the substrate), through the semiconductor material, and into the layer of the insulator material, the first conductive via is electrically connected to a first capacitor electrode of the capacitor, and the second conductive via is electrically connected to a second capacitor electrode of the capacitor.
Example 18 provides the IC structure according to example 17, in which the first conductive via is electrically connected to a terminal of the transistor.
Example 19 provides an IC structure that includes a substrate having a first side and a second side; a semiconductor material over the first side of the substrate, the semiconductor material including gallium and nitrogen; an insulator material over the semiconductor material; a transistor over the first side of the substrate, in which a portion of the semiconductor material is a channel region of the transistor; a first conductive via; a second conductive via; and a magnetic inductor including a structure of a magnetic material (e.g., a magnetic core of the magnetic inductor) extending from the second side of the substrate into the substrate, in which: the first conductive via and the second conductive via extend from the second side of the substrate to the first side of the substrate (e.g., extending through the substrate), through the semiconductor material, and into the layer of the insulator material, the first conductive via is electrically connected to the second conductive via, and the structure of the magnetic material is between the first conductive via and the second conductive via.
Example 20 provides the IC structure according to example 19, in which at least a portion of the transistor is vertically stacked above the structure of the magnetic material.
Example 21 provides the IC structure according to any one of the preceding examples, in which the substrate includes silicon.
Example 22 provides the IC structure according to any one of examples 1-21, in which the IC structure includes or is a part of a central processing unit.
Example 23 provides the IC structure according to any one of examples 1-21, in which the IC structure includes or is a part of a memory structure.
Example 24 provides the IC structure according to any one of examples 1-21, in which the IC structure includes or is a part of a logic circuit.
Example 25 provides the IC structure according to any one of examples 1-21, in which the IC structure includes or is a part of input/output circuitry.
Example 26 provides the IC structure according to any one of examples 1-21, in which the IC structure includes or is a part of a power delivery circuitry.
Example 27 provides an IC package that includes an IC die including an IC structure according to any one of examples 1-26; and a further IC component, coupled to the IC die.
Example 28 provides the IC package according to example 27, where the further IC component includes a package substrate.
Example 29 provides the IC package according to example 27, where the further IC component includes an interposer.
Example 30 provides the IC package according to example 27, where the further IC component includes a further IC die.
Example 31 provides a computing structure that includes a carrier substrate and an IC structure coupled to the carrier substrate, where the IC structure is an IC structure according to any one of examples 1-26, or the IC structure is included in the IC package according to any one of claims 27-30.
Example 32 provides the computing structure according to example 31, where the computing structure is a wearable or handheld computing structure.
Example 33 provides the computing structure according to examples 31 or 32, where the computing structure further includes one or more communication chips.
Example 34 provides the computing structure according to any one of examples 31-33, where the computing structure further includes an antenna.
Example 35 provides the computing structure according to any one of examples 31-34, where the carrier substrate is a motherboard.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a substrate having a first side and a second side;
a semiconductor material over the first side of the substrate, the semiconductor material comprising gallium and nitrogen;
a first conductive via; and
a second conductive via,
wherein:
the first conductive via and the second conductive via extend from the second side of the substrate to the first side of the substrate and into the semiconductor material, and
a distance between the second side of the substrate and an end of the first conductive via in the semiconductor material is different from a distance between the second side of the substrate and an end of the second conductive via in the semiconductor material.

2. The IC structure according to claim 1, wherein the first conductive via and the second conductive via are electrically isolated from all signal and power pathways in the IC structure.

3. The IC structure according to claim 1, wherein at least one of the first conductive via and the second conductive via is electrically connected to a ground pathway.

4. The IC structure according to claim 1, wherein:
the semiconductor material is a first semiconductor material,
the IC structure further includes a second semiconductor material over the first side of the substrate, the second semiconductor material comprising aluminum and nitrogen,
the second semiconductor material is between the substrate and the first semiconductor material, and
the first conductive via and the second conductive via extend through the second semiconductor material.

5. The IC structure according to claim 4, wherein a thermal conductivity of the second semiconductor material is lower than a thermal conductivity of the first semiconductor material.

6. The IC structure according to claim 4, wherein:
the IC structure further includes a third semiconductor material over the first side of the substrate, the third semiconductor material comprising aluminum and nitrogen and having a different material composition than the second semiconductor material,
the third semiconductor material is between the substrate and the second semiconductor material,
the second semiconductor material is between the third semiconductor material and the first semiconductor material, and
the first conductive via and the second conductive via extend through the third semiconductor material.

7. The IC structure according to claim 1, further comprising:
a transistor over the first side of the substrate,
wherein a portion of the semiconductor material is a channel region of the transistor.

8. The IC structure according to claim 7, further comprising:
a layer of an insulator material over the semiconductor material; and
a third conductive via,
wherein:
the third conductive via extends from the second side of the substrate to the first side of the substrate, through the semiconductor material, and into the layer of the insulator material, and
the third conductive via is electrically connected to a terminal of the transistor.

9. The IC structure according to claim 7, further comprising:
a layer of an insulator material over the semiconductor material; and
a third conductive via,
wherein:
the third conductive via extends from the second side of the substrate to the first side of the substrate, through the semiconductor material, and into the layer of the insulator material, and
the third conductive via is electrically connected to a signal pathway or a power pathway in the IC structure.

10. The IC structure according to claim 1, further comprising:
a capacitor extending from the second side of the substrate into the substrate.

11. The IC structure according to claim 10, further comprising:
a layer of an insulator material over the semiconductor material;
a third conductive via; and
a fourth conductive via,
wherein:
the third conductive via and the fourth conductive via extend from the second side of the substrate to the first side of the substrate, through the semiconductor material, and into the layer of the insulator material,
the third conductive via is electrically connected to a first capacitor electrode of the capacitor, and
the fourth conductive via is electrically connected to a second capacitor electrode of the capacitor.

12. The IC structure according to claim 11, further comprising:
a transistor over the first side of the substrate,
wherein:
a portion of the semiconductor material is a channel region of the transistor, and
the third conductive via is electrically connected to a terminal of the transistor.

13. The IC structure according to claim 1, further comprising:
a magnetic inductor comprising a structure of a magnetic material,
wherein the structure of the magnetic material extends from the second side of the substrate into the substrate.

14. The IC structure according to claim 13, further comprising:
a layer of an insulator material over the semiconductor material;
a third conductive via;
a fourth conductive via; and
a conductive interconnect in the layer of the insulator material,
wherein:
the third conductive via and the fourth conductive via extend from the second side of the substrate to the first side of the substrate, through the semiconductor material, and into the layer of the insulator material,
the conductive interconnect is electrically connected to the third conductive via and the fourth conductive via, and
the structure of the magnetic material is between the third conductive via and the fourth conductive via.

15. The IC structure according to claim 13, further comprising:
a transistor over the first side of the substrate,
wherein:
a portion of the semiconductor material is a channel region of the transistor, and
at least a portion of the transistor is vertically stacked above the structure of the magnetic material.

16. The IC structure according to claim 13, further comprising:
a capacitor extending from the second side of the substrate into the substrate.

17. An integrated circuit (IC) structure, comprising:
a substrate having a first side and a second side;
a semiconductor material over the first side of the substrate, the semiconductor material comprising gallium and nitrogen;
an insulator material over the semiconductor material;
a transistor over the first side of the substrate, wherein a portion of the semiconductor material is a channel region of the transistor;
a first conductive via;
a second conductive via; and
a capacitor extending from the second side of the substrate into the substrate,
wherein:
the first conductive via and the second conductive via extend from the second side of the substrate to the first side of the substrate, through the semiconductor material, and into the insulator material,
the first conductive via is electrically connected to a first capacitor electrode of the capacitor, and
the second conductive via is electrically connected to a second capacitor electrode of the capacitor.

18. The IC structure according to claim 17, wherein the first conductive via is electrically connected to a terminal of the transistor.

19. An integrated circuit (IC) structure, comprising:
a substrate having a first side and a second side;
a semiconductor material over the first side of the substrate, the semiconductor material comprising gallium and nitrogen;
an insulator material over the semiconductor material;
a transistor over the first side of the substrate, wherein a portion of the semiconductor material is a channel region of the transistor;
a first conductive via;
a second conductive via; and
a magnetic inductor comprising a structure of a magnetic material extending from the second side of the substrate into the substrate,
wherein:
the first conductive via and the second conductive via extend from the second side of the substrate to the first side of the substrate, through the semiconductor material, and into the insulator material,
the first conductive via is electrically connected to the second conductive via, and
the structure of the magnetic material is between the first conductive via and the second conductive via.

20. The IC structure according to claim 19, wherein at least a portion of the transistor is vertically stacked above the structure of the magnetic material.
